(19) United States
(12) Patent Application Publication
(10) Pub. No.: US 2025/0275074 A1
(43) Pub. Date: Aug. 28, 2025

(54) LID INSERT AND COVER FOR A UTILITY BOX ENABLING INSTRUMENTATION SIGNALS

(71) Applicant: Bingham & Taylor Corp., Rocky Hill, CT (US)

(72) Inventors: Dennis Quinn, Boston, VA (US); James Klopp, Orange, VA (US); James Bryant, Culpeper, VA (US); Jacob Butcher, Fredericksburg, VA (US)

(73) Assignee: Bingham & Taylor Corp., Rocky Hill, CT (US)

(21) Appl. No.: 18/813,494

(22) Filed: Aug. 23, 2024

Related U.S. Application Data
(60) Provisional application No. 63/556,782, filed on Feb. 22, 2024.

(51) Int. Cl. H05K 5/03; H01Q 1/22

(52) U.S. Cl. CPC H05K 5/03; H01Q 1/2233

(57) ABSTRACT

Systems and methods are disclosed for a lid insert and cover for use with a utility box having any type of instrument, e.g., a leak detection or geo-location instrument, with an antenna for transmitting any type of signals related to the instrument, e.g., a leak detection, geo-location or electrical current or load sensing signal. The insert may include a top plate configured to be mounted in an upper recess of the cover and a bottom plate configured to be mounted in a lower recess of the cover. The bottom plate may define a plurality of openings for fasteners, e.g., screws, bolts or other mechanical mounting mechanisms and/or zip-ties, that are configured for securing the instrument and/or its antenna within the box. When properly mounted therein, the antenna of such instruments can effectively transmit or receive signals into and out of the utility box.

### CROSS-REFERENCE TO RELATED APPLICATIONS

This application claims benefit of U.S. Provisional Application No. 63/556,782, filed Feb. 22, 2024, and entitled Lid Insert and Cover for a Utility Meter Box with Leak Detection the entire disclosure of which is incorporated herein by reference for all purposes.

### FIELD OF THE INVENTION

The present disclosure relates to a lid insert and cover for use with a utility box, and more specifically to a lid insert and cover, for use with a utility box, that are configured to secure a variety of different types of instrumentation particularly those having antennas for the transmission and/or receipt of data. Examples of such instrumentation include, without limitation, leak detection, geo-location, electrical utility instrumentation, gas utility instrumentation, communication instrumentation or any other type of monitoring instrument utility box.

### BACKGROUND

The present disclosure relates to any kind of box, housing or container that houses utility equipment, regardless of its function. For the purposes of simplicity only, such boxes, housings and/or container are referred to collectively herein as utility boxes, although it should be recognized that the present disclosure is not limited to any particular type of utility box or any particular function, e.g., metering. Thus, while the term utility box is used herein, its should be appreciated that such term refers to, without limitation, to valve boxes, curb boxes, meter boxes, meter pits, valve vaults, meter vaults, etc.

Utility boxes are very commonly employed by, e.g., municipalities or other utility-providing or servicing entities and the like, to house equipment of varying types, such as water flow meters, gas flow meters, utility meters, electrical meters, geo-location equipment, communication instrumentation, or the like, any of which may transmit and/or receive data signals in connection therewith. In addition, along with these and any other type of equipment, the utility box may also include various types of monitoring instruments which may detect certain conditions and which may transmit and/or receive data in connection therewith. For example, one such type of instrument that may be commonly stored within a utility box is a leak detection instrument, which is configured to detect when a leak has occurred within the water distribution system. Another such type of instrument that may be commonly stored within a utility box is a geo-location instrument, which allows for the location and identification of underground utilities, as will be described in additional detail below. A third such type of instrument that may be commonly stored within a utility box is an electrical current or electrical load sensing device that monitors electrical power consumption in an electric power distribution network. Various other types of instruments are also commonly employed.

As mentioned above, these monitoring or metering instruments, e.g., a leak detection or geo-location instrument, typically employ an antenna so as to transmit or receive data signals related thereto, such as a signal indicating that a leak has occurred, a signal providing location data, or a variety of other signals. Ideally, because the purpose of such instruments is to provide data when a person is not physically present at the device, the lid of such a utility box is preferably able to transmit such a signal through the lid (since a person is not physically present to remove the lid first).

Such monitoring instruments, and the antennae employed therewith, often come in a variety of different sizes and types. However, such various types of utility box lids suffer from certain challenges, e.g., an inability to effectively secure different types of antennae, while still ensuring that the lid allows signals to be transmitted therethrough, or being of insufficient strength to be installed in the required location, e.g. a roadway or sidewalk where vehicular traffic and forces are present.

### SUMMARY

The following presents a simplified summary of the claimed subject matter in order to provide a basic understanding of some aspects of the claimed subject matter. This summary is not an extensive overview of the claimed subject matter. It is intended to neither identify key or critical elements of the claimed subject matter nor delineate the scope of the claimed subject matter. Its sole purpose is to present some concepts of the claimed subject matter in a simplified form as a prelude to the more detailed description that is presented later.

The various types of utility box lid and cover systems described hereinbelow, according to various embodiments, address various challenges facing previously-employed utility box lid inserts. Utility boxes often endure a significant amount of wear-and-tear, and thus the antennae used therein are often required to be regularly replaced. If, at the time that an antenna needs to be replaced, the antenna type has changed from the previous antenna type, the existing utility box lid may not be configured to effectively secure the new antenna while still enabling the new antenna's signal to be transmitted. This could result in the entire utility box, or at least the lid of the utility box, needing to be replaced, at very significant cost of time and money.

In contrast, a particular advantage of the lid insert and cover described herein is that they include structural features that render them suitable for effectively securing various different types of instrumentation and/or antennae, while still ensuring that the lid allows signals to be transmitted therethrough. Still further, by manufacturing a single type of lid insert and cover to be used for various different instrumentation and/or antenna types, the manufacturer of the lid insert and/or cover can enjoy significant manufacturing costs savings, e.g., by requiring only a single molding tool for a given size of lid insert and/or cover, rather than multiple molding tools, and can pass those cost savings onto customers such as municipalities and other utility entities (and hence save taxpayer money too). In addition, by manufacturing a single type of lid insert and/or cover to be used for various different instrumentation and/or antenna types, a manufacturer can provide significant cost savings for its own, as well as its customers', administrative tasks by enabling easier storage and selection of only a single lid insert and/or cover, rather than multiple lid inserts and covers, and can again pass those costs savings onto customers and taxpayers. Still further, by manufacturing a single type of lid insert and/or cover to be used for various different instrumentation and/or antenna types, a customer such as a municipality or other water/utility entity can avoid confusion when selecting a suitable lid insert and cover to be installed within a utility box, since the lid insert and/or cover may be suitable for any encountered instrumentation and/or antenna type, thereby potentially avoiding or reducing installation errors and/or equipment failures or damage.

As set forth, there is no limitation to the number or type of instruments or equipment that may be employed with the meter lid insert and cover systems described herein. Although several embodiments are set forth below for the purpose of providing examples, these embodiments should be considered nonlimiting, and the features of any such embodiment described for use with a specific type of instrumentation could be employable in different embodiments for use with a different type of instrumentation.

One example of instrumentation, that may be employed in the meter lid insert and cover systems described herein, includes leak detection instruments. Leak detection instruments are configured to detect when a leak, e.g., of gas or water, has occurred within the water distribution system, and to transmit a data signal corresponding thereto from the meter box to a remote location. In this way, the utility service provider can be notified of a leak and send personnel to investigate and/or fix the leak.

Another example of instrumentation, that may be employed in the meter lid insert and cover systems described herein, includes geo-location instrumentation. Geo-location is a technology that allows for the location and identification of underground utilities. For example, geo-location may be used to help locate utilities such as power, water, gas, fiber, and other communications. A geo-location device, typically an RFID, may allow for two-way communication with a locator unit, and thus requires an environment that allows for good signal strength and communication with its locator and programmer units. There are a variety of different geo-location systems and communication protocols.

Still another example of instrumentation, that may be employed in the meter lid insert and cover systems described herein, includes electrical and other utility instrumentation. Electrical utility providers often have underground lines below roadways. Although such electrical utility providers employ such meter boxes in every conceivable location, electrical utility providers in cities and high population density areas often have a particularly strong need for meters such as load monitors, surge monitors, fault current indicators, among a variety of other types of monitoring instruments. Cellular and radio-based transmitters are common in these applications, and thus, for these and other such applications, the meter lid insert and cover systems described in the embodiments below are particularly well-suited.

Of course, still other examples of instrumentation, that may be employed in the meter lid insert and cover systems described herein, include without limitation, gas utility instrumentation, communication instrumentation, or any other conceivable type of monitoring instrument. As set forth above, the features described hereinbelow in connection with any specific type of instrument should also be considered applicable to any other type of equipment.

For example, in an embodiment, there is provided a lid for mounting on a utility box, the utility box housing an antenna therein. The utility box may house a leak detection instrument, and the antenna may be configured to transmit a signal generated by the leak detection instrument. The lid may comprise a cover configured to be mounted on the utility box. The lid may also comprise an insert configured to be mounted to the cover, the insert including a plurality of fastening mechanisms configured to secure the antenna such that the antenna can transmit a signal out of the utility box. The antenna may be selected from a plurality of different antenna configurations, and the plurality of fastening mechanism may be configured to secure any one of the plurality of different antenna configurations antenna such that any one of the plurality of different antenna configurations can transmit a signal out of the utility box. The plurality of fastening mechanisms may be an opening for receiving at least one of a zip-tie and a screw.

In embodiments, the cover may include a through-hole extending from a top surface of the cover to a bottom surface of the cover. The through-hole may include a shelf in between the top surface of the cover and the bottom surface of the cover, the portion of the through-hole above the shelf defining an upper recess and the portion of the through-hole below the shelf defining a lower recess. The insert may comprise a top plate configured to be mounted in the upper recess of the cover and a bottom plate configured to be mounted in the lower recess of the cover. The top plate and the bottom plate may be configured to be secured to each other, with the shelf interposed therebetween, by one or more screws that extend upwardly through the bottom plate and into complementary screw openings in the upper plate.

Additionally or alternatively, the top plate and the bottom plate may be configured to be secured to each other, with the shelf interposed therebetween, by a twist lock mechanism that secures the bottom plate to the upper plate. The twist lock mechanism may include a plurality of complementary slots and tabs that secure the bottom plate to the upper plate. The twist lock mechanism may include one of a wave washer, a rubber gasket or an o-ring to apply a force that helps maintain the complementary tabs within the slots so as to secure the bottom plate to the upper plate.

In still further embodiments, there is provided an insert, e.g., manufactured from plastic, for mounting to a utility box cover of a utility box, the utility box housing an antenna therein. The utility box may house a leak detection instrument, and the antenna may be configured to transmit a signal generated by the leak detection instrument. The insert may comprise a top plate configured to be mounted in an upper recess of the cover and a bottom plate configured to be mounted in a lower recess of the cover. The bottom plate may define a plurality of fastener openings, each fastener opening configured to receive a fastener for securing the antenna such that the antenna can transmit a signal out of the utility box. The fastener may be one of a zip-tie and a screw.

In embodiments, the top plate and the bottom plate may be configured to be secured to each other, with at least a portion of the utility box cover plate interposed therebetween, by an insert attachment mechanism. The insert attachment mechanism may include one or more screws that extend upwardly through the bottom plate and into complementary screw openings in the upper plate. Of course, it should be recognized that the insert attachment mechanism may additionally or alternatively extend downwardly, and/or perpendicular to the axis of the parts. Other joining methods are also possible including, but not limited to, adhesives (including glues, epoxies, urethanes, and acrylics), tapes, hook and loop fasteners (e.g., Velcro), and/or plastic welding (including ultrasonic and thermal/friction welding).

Additionally or alternatively, the insert attachment mechanism may include a twist lock mechanism that secures the bottom plate to the upper plate. The twist lock mechanism may include a plurality of complementary slots and tabs that secure the bottom plate to the upper plate. The twist lock mechanism may include one or more of a spring, including wave washer springs, coil springs, torsion springs, a rubber or rubber-like gasket, or an o-ring to apply a force that helps maintain the tabs within the complementary slots so as to secure the bottom plate to the upper plate. The twist lock mechanism may include at least one anti-backout features so as to help secure the tabs within the complementary slots.

In still further embodiments, there is provided a method for assembling a lid for a leak detection system of a utility box. The method may comprise the step of providing a cast-iron or other metal cover configured to be mounted on the utility box, the cover including an upper recess and a lower recess with a shelf disposed therebetween. The method may comprise the steps of providing a plastic insert top plate, and providing a plastic insert bottom plate having a fastening mechanism configured to secure an antenna. The method may also comprise the step of mounting the insert top plate and the insert bottom plate to the cover by securing the top plate to the bottom plate, with the top plate residing in the upper recess and the bottom plate residing in the lower recess and having the shelf interposed therebetween. The fastening mechanism may be at least one opening for receiving at least one of a zip-tie, screw, rivet, pin, retaining ring, or other standard, commonly available fastening device.

In such embodiments, the mounting step may include screwing the insert top plate to the insert bottom plate. The mounting step may include twist-locking the insert top plate to the insert bottom plate. The method may also comprise the steps of mounting the lid on a utility box having a leak detection instrument therein, the leak detection instrument including the antenna, and fastening the antenna to the insert bottom plate via the fastening mechanism such that the antenna is positioned to transmit a leak detection signal through the lid. In still other embodiments, the insert may be a single component, e.g., a single plate rather than an upper and a bottom plate, that is secured directly to the cast iron/metal lid. In still further embodiments, the upper and bottom plates may be connected via a snap-fit type connection system, whereby the upper and bottom plates slide together relative to each other along a common axis to snap fit together.

Still further, the method may include the steps of unfastening the antenna from the fastening mechanism, replacing the antenna of the leak detection instrument with a different antenna, and fastening the different antenna to the bottom plate via the fastening mechanism such that the different antenna is also positioned to transmit a leak detection signal through the lid. This may be accomplished by the use of various brackets designed and manufactured to mate the desired antennae with the mounting geometry of the insert. In this way, the method permits for the use of varying types of antennas using the same lid insert.

### DRAWINGS

FIG. 1 shows a bottom perspective view of a lid insert, in accordance with various embodiments.

FIG. 2A shows a top view of the lid insert of FIG. 1 assembled into a cover for use with a utility box, in accordance with various embodiments.

FIG. 2B shows a side cross-sectional view of the assembled insert and cover shown in FIG. 2A, taken along cross-section A-A of FIG. 2A, in accordance with various embodiments.

FIG. 2C shows a side cross-sectional view of the assembled insert and cover shown in FIG. 2A, along with a schematic representation of utility box having an instrument with an antenna therein, in accordance with various embodiments.

FIG. 3 shows a bottom perspective view of an alternative lid insert, in accordance with various embodiments.

FIG. 4A shows a top view of the lid insert of FIG. 3 assembled into a cover for use with a utility box, in accordance with various embodiments.

FIG. 4B shows a side cross-sectional view of the assembled insert and cover shown in FIG. 4A, taken along cross-section A-A of FIG. 4A, in accordance with various embodiments.

FIG. 5A is a top perspective view of a cover, without the insert installed therein, for a utility box, in accordance with various embodiments.

FIG. 5B is a top view of the cover shown in FIG. 5A, in accordance with various embodiments.

FIG. 5C is a bottom view of the cover shown in FIG. 5A, in accordance with various embodiments.

FIG. 5D is a side cross-sectional view of the cover shown in FIG. 5A, in accordance with various embodiments.

FIG. 6A is a top perspective view of a cover, without the insert installed therein, for a utility box, in accordance with various embodiments.

FIG. 6B is a top view of the cover shown in FIG. 6A, in accordance with various embodiments.

FIG. 6C is a bottom view of the cover shown in FIG. 6A, in accordance with various embodiments.

FIG. 6D is a side cross-sectional view of the cover shown in FIG. 6A, in accordance with various embodiments.

FIG. 7A is a top perspective view of a cover, without the insert installed therein, for a utility box, in accordance with various embodiments.

FIG. 7B is a top view of the cover shown in FIG. 7A, in accordance with various embodiments.

FIG. 7C is a bottom view of the cover shown in FIG. 7A, in accordance with various embodiments.

FIG. 7D is a side cross-sectional view of the cover shown in FIG. 7A, in accordance with various embodiments.

FIG. 8A is an exploded side perspective view of a lid, in accordance with various embodiments.

FIG. 8B is a top perspective view of a lid, in accordance with various embodiments.

FIG. 8C is a top view of a lid, in accordance with various embodiments.

FIG. 8D is a side cross-sectional view of the assembled insert and the cover, taken along cross-section A-A of FIG. 8C, in accordance with various embodiments.

FIG. 8E is a bottom view of a lid, in accordance with various embodiments.

FIG. 9A shows an exploded side perspective view of a lid including an insert, in accordance with various embodiments.

FIG. 9B is a top perspective view of a lid, in accordance with various embodiments.

FIG. 9C is a top view of a lid, in accordance with various embodiments.

FIG. 9D is a side cross-sectional view of an assembled insert and the cover, taken along cross-section A-A of FIG. 9C, in accordance with various embodiments.

FIG. 9E is a bottom view of a lid, in accordance with various embodiments.

FIG. 10A shows an exploded side perspective view of a lid, in accordance with various embodiments.

FIG. 10B is a top view of the lid, in accordance with various embodiments.

FIG. 10C is a side view of the lid 910, in accordance with various embodiments.

FIG. 10D is a side cross-sectional view of an assembled insert and cover, taken along cross-section A-A of FIG. 10C in accordance with various embodiments.

FIG. 11A shows an exploded side perspective view of a lid including an insert, in accordance with various embodiments.

FIG. 11B is a top view of the insert, in accordance with various embodiments.

FIG. 11C is a side cross-sectional view of the assembled insert and the cover, taken along cross-section A-A of FIG. 11B, in accordance with various embodiments.

FIG. 12A shows a cutaway top perspective view of a lid including an insert, in accordance with various embodiments.

FIG. 12B is a top view of the assembled lid, in accordance with various embodiments.

FIG. 12C is a bottom view of the assembled lid, in accordance with various embodiments.

FIG. 12D illustrates a side cross-sectional view of the assembled insert and the cover, taken along cross-section D-D of FIG. 12B, in accordance with various embodiments.

FIG. 13A shows a top plate in a top perspective view, in accordance with various embodiments.

FIG. 13B illustrates the top plate in a top view, in accordance with various embodiments.

FIG. 13C illustrates the top plate in a bottom view, in accordance with various embodiments.

FIG. 14A shows a bottom plate in a top perspective view, in accordance with various embodiments.

FIG. 14B illustrates the bottom plate in a top view, in accordance with various embodiments.

FIG. 14C illustrates the bottom plate in a bottom view, in accordance with various embodiments.

FIGS. 14D and 14E are side views of a bottom plate illustrating circumferentially-disposed tabs and the oppositely-disposed fingers extending downwardly from the bottom surface of the bottom plate, in accordance with various embodiments.

FIG. 15A shows an instrument/antenna retainer in a top perspective view, in accordance with various embodiments.

FIG. 15B illustrates the instrument/antenna retainer in a top view, in accordance with various embodiments.

FIG. 15C illustrates the instrument/antenna retainer in a side view, in accordance with various embodiments.

FIG. 15D illustrates the instrument/antenna retainer in a side cross-sectional view, in accordance with various embodiments.

### DETAILED DESCRIPTION

Reference will now be made in detail to specific embodiments illustrated in the accompanying drawings. In the following detailed description, numerous specific details are set forth to provide a thorough understanding. However, it will be apparent to one of ordinary skill in the art that embodiments may be practiced without these specific details. In other instances, known methods, procedures and/or components have not been described in detail so as not to unnecessarily obscure aspects of the embodiments.

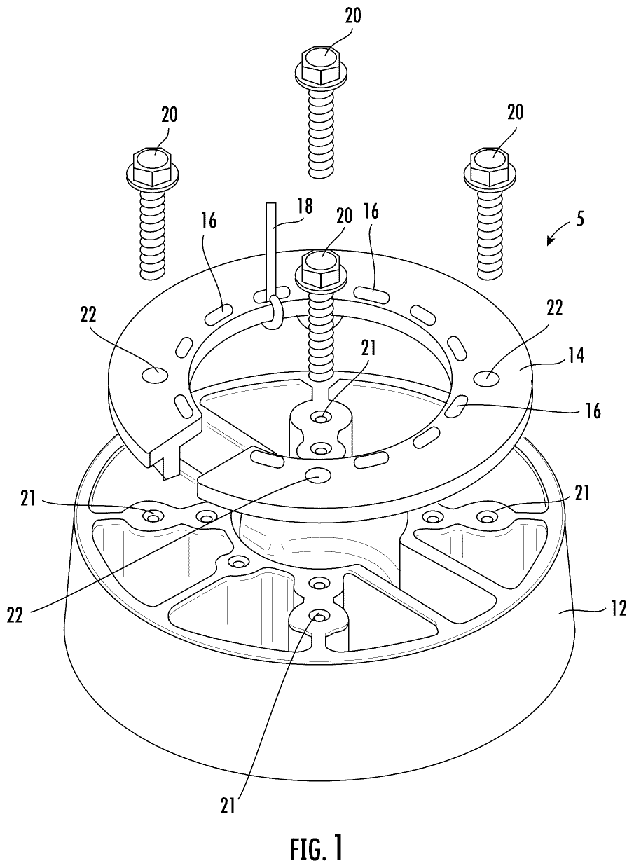

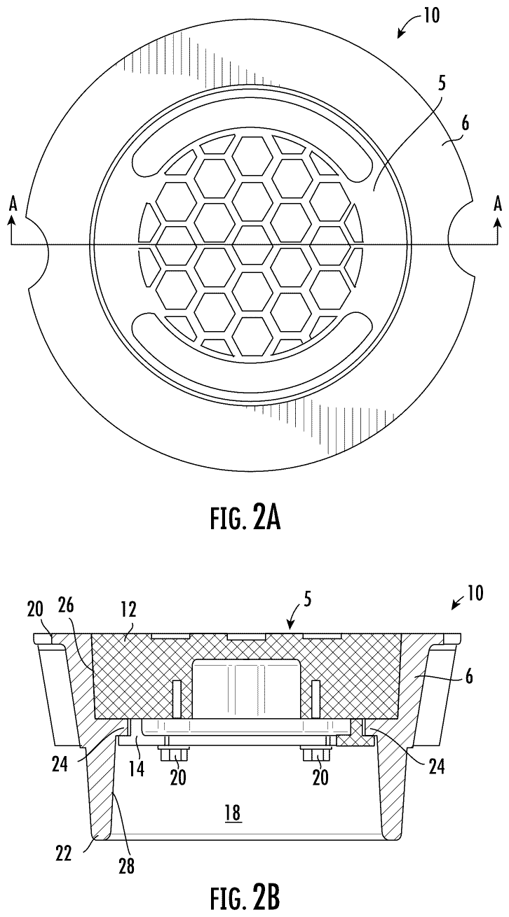

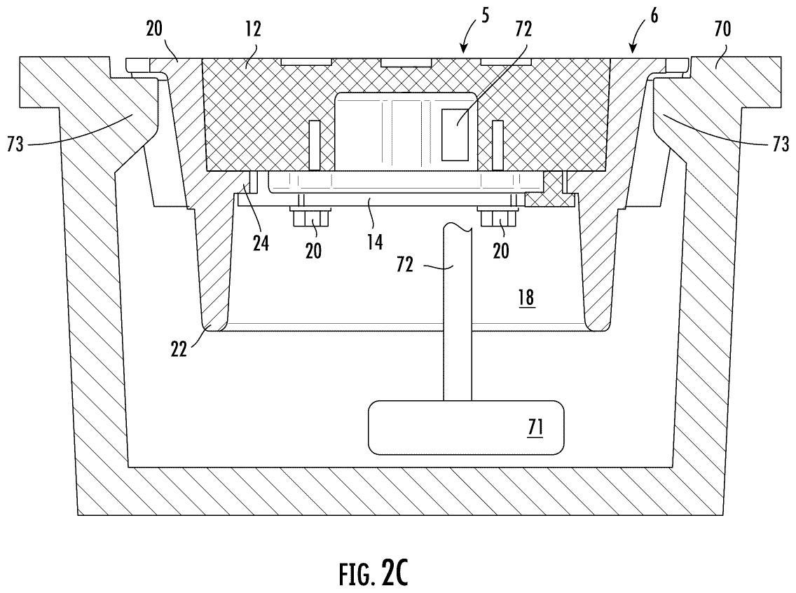

As set forth above, FIG. 1 shows a bottom perspective view of an insert 5 that is configured to be assembled with a cover 6 (shown and described in further detail below in FIGS. 2A-B), the insert 5 and cover 6 together forming a lid 10 for a utility box (not shown), in accordance with various embodiments. According to an example embodiment, the lid 10 is configured for covering a utility box that includes a leak detection instrument having an antenna, as will be further shown and described below in connection with FIG. 2C. It should be noted that FIG. 1 is merely exemplary, and thus the shape and position of the various features illustrated therein, and in the other figures, are merely examples. Additional figures, illustrating specific embodiments of various features and functionality, will be provided in further detail below.

In the embodiment shown in FIG. 1, the insert 5 includes a top plate 12 and a bottom plate 14. The bottom plate 14 defines a plurality of fastener openings 16. Each fastener opening 16 is configured to receive a fastener 18 for securing the antenna such that the antenna can transmit a signal out of the utility box. In various embodiments, the fastener 18 may be a zip-tie (as shown) or a screw (not shown) or any other type of fastener 18 capable of securing the antenna.

As shown in FIG. 1, the top plate 12 and the bottom plate 14 are configured to be secured to each other by an insert attachment mechanism, such as by one or more screws or bolts (referred to as screws 20 hereinafter for simplicity only) that extend upwardly through holes 22 in the bottom plate 14 and into complementary openings 21 in the upper plate 12. It should be appreciated that the screws 20 may be self-tapping, e.g., may be configured to themselves create threads in the openings 21, or the openings 21 may instead have threaded inserts into which the screws 20 may be fastened. It should be recognized that the insert attachment mechanism may additionally or alternatively extend downwardly, and/or perpendicular to the axis of the parts. Other joining methods are also possible including, but not limited to, adhesives (including glues, epoxies, urethanes, and acrylics), tapes, hook and loop fasteners (e.g., Velcro), and/or plastic welding (including ultrasonic and thermal/friction welding).

In FIG. 2A there is shown a top view of the insert 10 of FIG. 1 assembled into a cover 6 so as to together form a lid 10 for use with a utility box, in accordance with various embodiments. Referring now to FIG. 2B, there is shown a side cross-sectional view of the assembled insert and cover shown in FIG. 2A, taken along cross-section A-A of FIG. 2A. As shown in FIG. 2B, the cover 6 may include a through-hole 18 extending from a top surface 20 of the cover 6 to a bottom surface 22 of the cover 6. The through-hole 18 may include a shelf 24 in between the top surface 20 of the cover 6 and the bottom surface 22 of the cover 6, the portion of the through-hole 18 above the shelf 24 defining an upper recess 26 and the portion of the through-hole 18 below the shelf 24 defining a lower recess 28. The top plate 12 of the insert 5 is configured to be mounted in the upper recess 26 of the cover 6 and a bottom plate 14 is configured to be mounted in the lower recess 28 of the cover 6. Advantageously, the top plate 12 and the bottom plate 14 are configured to be secured to each other, e.g., by the attachment screws 20, such that the shelf 24 is interposed between the top plate 12 and the bottom plate 14, thereby securing the insert 5 to the cover 6.

For the purposes of illustration, FIG. 2C shows a side cross-sectional view of the assembled insert and cover shown in FIG. 2A, but in this figure also illustrates the components along with a schematic representation of utility box 70 having an instrument 71, e.g., a leak detection instrument 71, with an antenna 72 therein, in accordance with various embodiments. Of course, it should be appreciated that the utility box 70 could have a variety of number of different instruments and equipment disposed therein, and that this figure is provided to show a simple example only of such a utility box. As set forth above, any type of utility box, utilized for housing any conceivable instrument having any conceivable purpose, is envisioned herein. The assembled insert and cover are shown in FIG. 2C as being supported by a lip 72 of the utility box 70, although various other support arrangements are also contemplated.

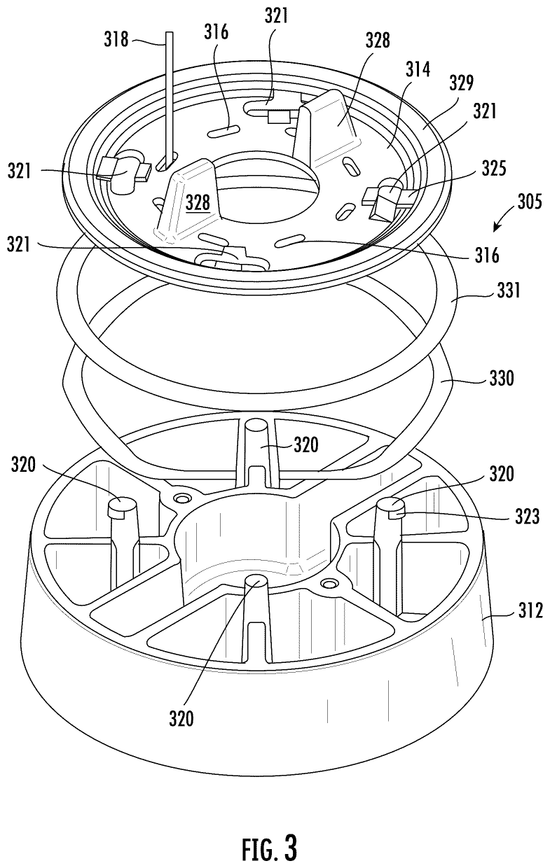

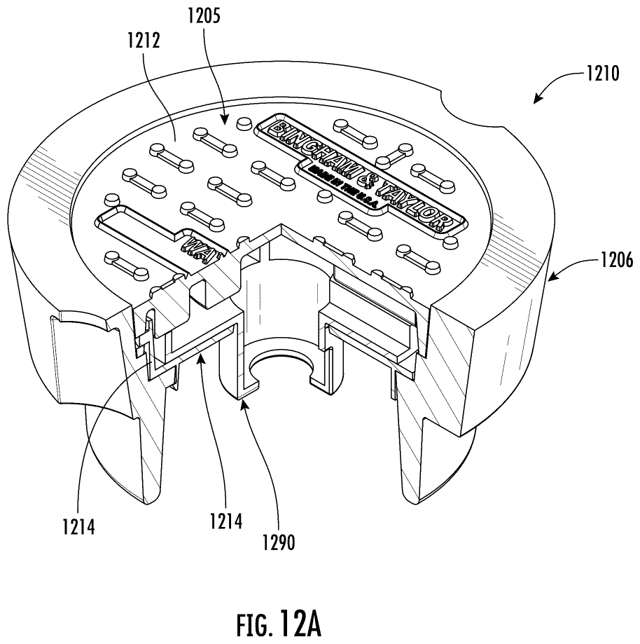

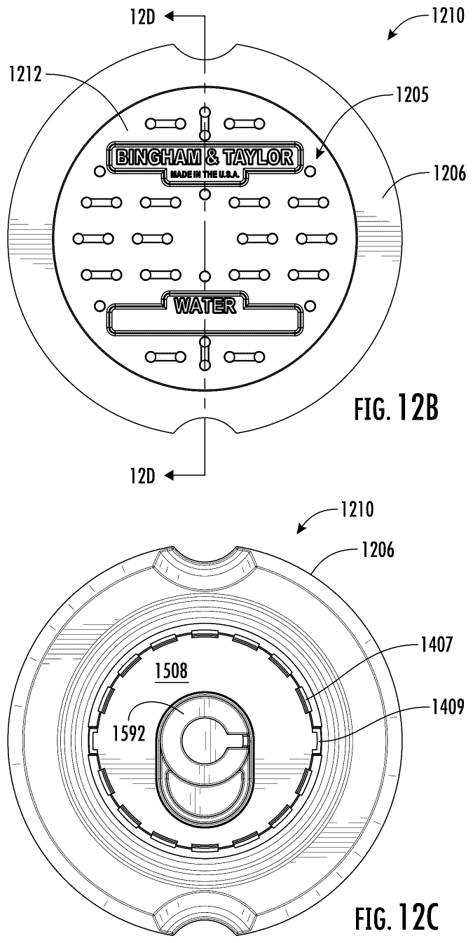

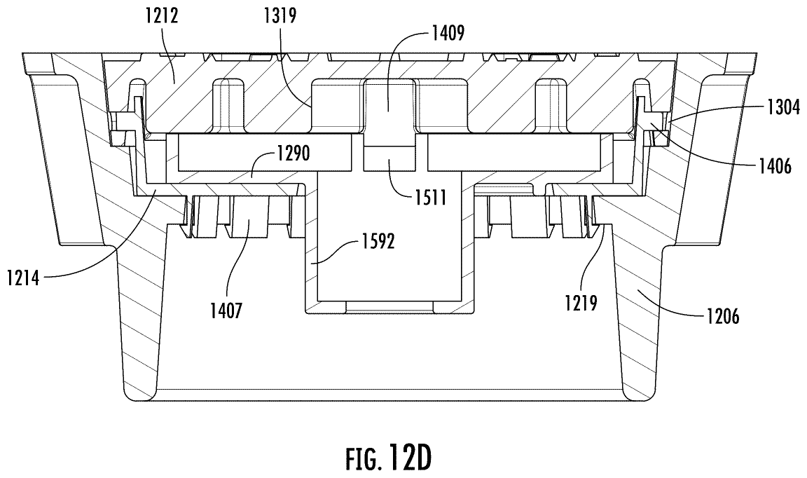

As set forth above, the top plate 12 and the bottom plate 14 are configured to be secured to each other by an insert attachment mechanism. While the embodiment shown in FIGS. 1 through 2B illustrate an embodiment in which the insert attachment mechanism are one or more screws or bolts that extend upwardly through holes 22 in the bottom plate 14 and into complementary openings 21 in the upper plate 12, other embodiments are provided having alternative insert attachment mechanisms. For example, FIG. 3 illustrates an embodiment in which the insert attachment mechanism includes a twist-lock mechanism. A twist-lock mechanism may be particularly well-suited for embodiments in which it is preferred that the top plate 12 and the bottom plate 14 be securable to each other—and thereby also collectively securable to the cover 6—without the use of additional components (e.g., without the use of screws 20 or the like) and/or without the use of tools (e.g., without the use of a screwdriver or the like to drive such screws). Of course, it should be recognized that, while the above-described embodiments illustrate certain mechanisms to connect the upper plate and the bottom plate to each other, there is no limitation on the various different ways that such connections may be achieved. For example, the same type of connection could be achieved, in other contemplated embodiments, via snap-in or push-on features or the like, adhesives, rivets or any other such connection mechanisms. For example, the upper and bottom plates may be connected via a snap-fit type connection system, whereby the upper and bottom plates slide together relative to each other along a common axis to snap fit together. An example embodiment illustrating such an arrangement is shown and described in additional detail below in connection with FIGS. 12A through 15D.

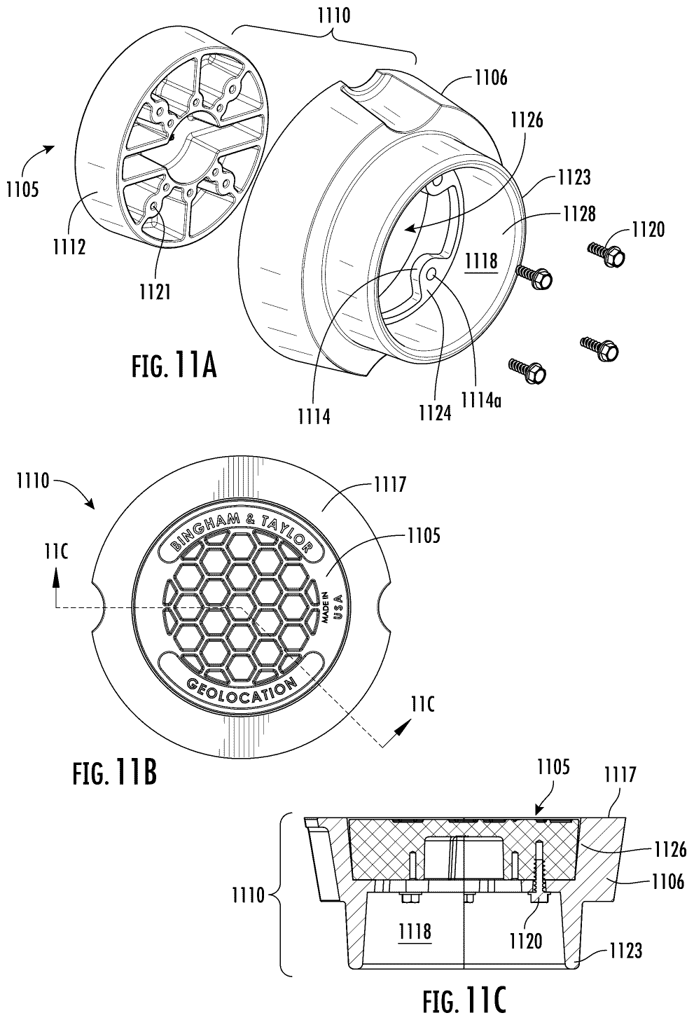

Still further, and as mentioned previously, it should be recognized that, while the above-described embodiments illustrate both an upper plate and a bottom plate being connected to each other, there are also contemplated embodiments in which there is only a single plate, e.g., screws or bolts that pass directly through the lid and into an upper plate without the need for a bottom plate. In other words, the insert may be a single component, e.g., a single plate rather than an upper and a bottom plate, that is secured directly to the cast iron/metal lid. An example embodiment illustrating such an arrangement is shown and described in additional detail below in connection with FIGS. 11A through 11C. Likewise, single plate embodiments are also envisioned in which snap-in features enable a single plate to be employed without the need for a second plate. Again, there is no limitation on the various different ways that such connections may be achieved.

Referring to FIG. 3, there is shown a bottom perspective view of an alternative lid insert 305, in accordance with various embodiments. The insert 305 includes a top plate 312 and a bottom plate 314. The bottom plate 314 defines a plurality of fastener openings 316. Each fastener opening 316 is configured to receive a fastener 318 for securing the antenna such that the antenna can transmit a signal out of the utility box. In various embodiments, the fastener 318 may be a zip-tie (as shown) or a screw (not shown) or any other type of fastener 318 capable of securing the antenna.

As shown in FIG. 3, the top plate 312 and the bottom plate 314 are configured to be secured to each other by a twist-lock mechanism. In this twist-lock mechanism, the top plate 312 includes tabs 320 that extend through complementary slots 321 in the bottom plate 314. It should be appreciated that the tabs 320 and slots 321 may have any suitable shapes that complement each other. In use, the tabs 320 are lined up with and inserted into the slots 321. Thereafter, the top plate 312 and the bottom plate 314 are twisted/rotated slightly relative to each other such that the tabs 320 move to a portion of the slot 321 from which the tabs 320 cannot be readily disengaged from.

To ensure that the top plate 312 and the bottom plate 314 remain secured to each other until they are specifically desired to be separated, one or more of the top plate 312 and the bottom plate 314 may have anti-backout features. For example, in the embodiment shown, the bottom plate 314 has, adjacent to its slots 321, a series of ridges or ramps 325 that engage protrusions 323 on the ends of the tabs 320. As the top plate 312 and the bottom plate 314 are twisted/rotated relative to each other, the protrusions 323 on the tabs 320 of the top plate 312 engage the ridges or ramps 325 of the slots 321 of the bottom plate 314 and are secured thereby.

To help maintain engagement between the protrusions 323 on the tabs 320 and the ridges or ramps 325 of the slots 321—and consequently help maintain the securement of the top plate 312 to the bottom plate 314 with the cover 6 interposed therebetween—the insert 305 may include one or more of a, e.g., wave washer 330 or a rubber gasket/o-ring 331 (both being shown in FIG. 3, although they may be employed separately or together). Rather than being a generally flat bottom plate 14 as is shown in FIG. 1, the the bottom plate 314 shown in FIG. 3 has a step 329 which provides some space for the wave washer 330 or a rubber gasket/o-ring 331 between the top plate 312 and the bottom plate 314.

The wave washer 330 and/or a rubber gasket/o-ring 331 function to apply a longitudinal force that pushes the bottom plate 314 away from the top plate 312. This longitudinal force helps maintain the tabs 320 within the complementary slots 321, secured therein by the anti-backout features of ridges/ramps 325, unless and until a user applies a greater force by pushing the top plate 312 and the bottom plate 314 towards each other, thereby disengaging the protrusions 323 from the ridges/ramps 325 and allowing the bottom plate 314 to be untwisted relative to the top plate 312 such that the top plate 312 and the bottom plate 314 can be separated from each other and from the cover 306.

To help facilitate the twisting of the top plate 312 relative to the bottom plate, the bottom plate 314 may also include fins 328 engageable by a user's hands. As mentioned above, the fins 328, by enabling a user to twist the top plate 312 relative to the bottom plate 314 with his or her hands, may provide the advantage of the user avoiding the use of tools (e.g., avoiding the use of a screwdriver or the like) to attach the top plate 312 to the bottom plate 314.

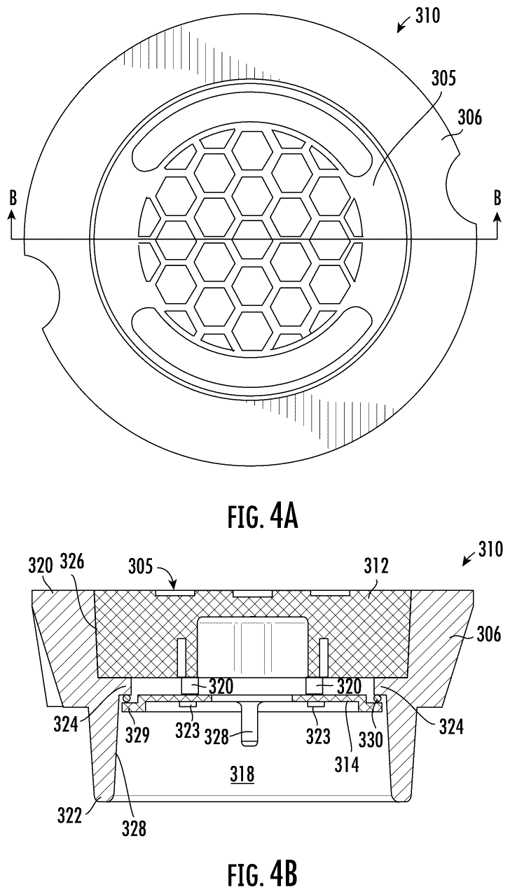

In FIG. 4A there is shown a top view of the insert 310 of FIG. 3 assembled into a cover 306 so as to together form a lid 310 for use with a utility box, in accordance with various embodiments. Referring now to FIG. 4B, there is shown a side cross-sectional view of the assembled insert 305 and cover 306 shown in FIG. 4A, taken along cross-section A-A of FIG. 4A. As shown in FIG. 4B, the cover 306 may include a through-hole 318 extending from a top surface 320 of the cover 306 to a bottom surface 322 of the cover 306. The through-hole 318 may include a shelf 324 in between the top surface 320 of the cover 306 and the bottom surface 322 of the cover 306, the portion of the through-hole 318 above the shelf 324 defining an upper recess 326 and the portion of the through-hole 318 below the shelf 324 defining a lower recess 328. The top plate 312 of the insert 305 is configured to be mounted in the upper recess 326 of the cover 306 and the bottom plate 314 is configured to be mounted in the lower recess 328 of the cover 306. FIG. 4B shows the protrusions 323 of the tabs 320 of the top plate 312 engaged within the slots 320 of the bottom plate 314. The gasket 331 (which could also be a wave washer 330) is shown in between the top plate 312 and the bottom plate 314 so as to maintain pressure therebetween of keeping the protrusions 323 maintained within the slots 320.

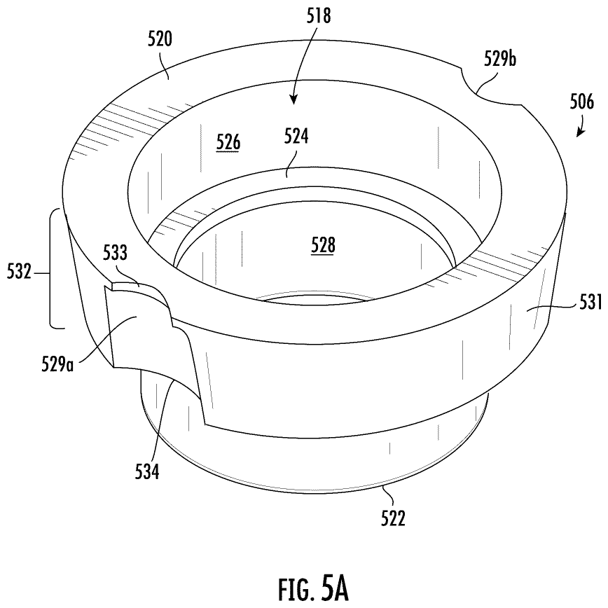

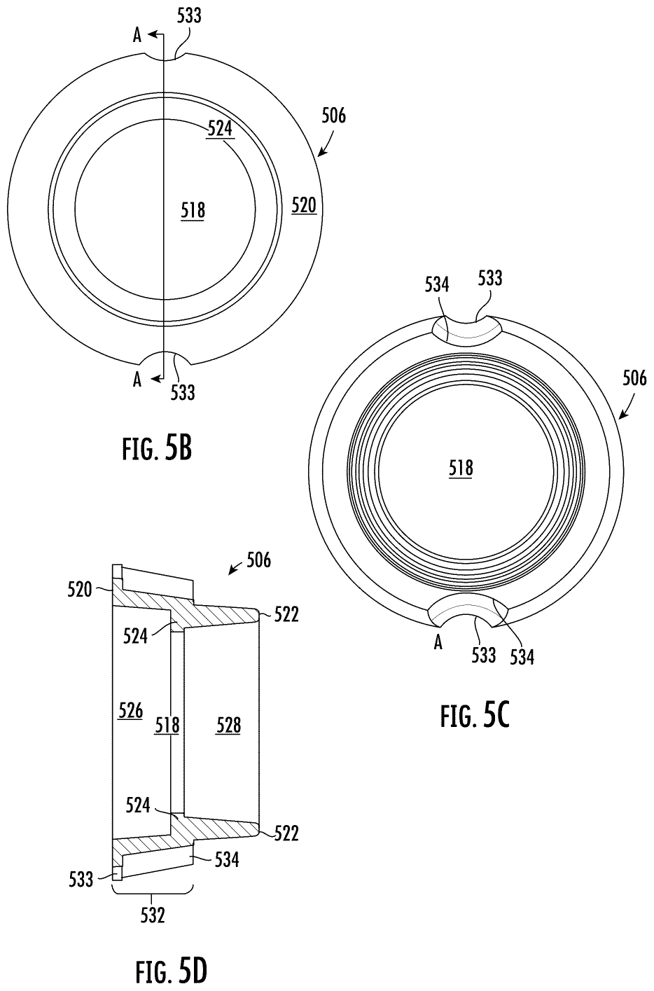

As set forth above, the lid inserts described herein are employed with covers, typically cast from cast-iron for strength and durability, that are configured to fit within an opening of a utility box. Because utility boxes may come in a variety of different sizes and configurations, the covers described herein may have various different sizes and configurations too. For example, FIGS. 5-7 illustrate several different cover configurations that may be employed to accommodate different sizes or types of utility boxes.

For example, FIG. 5A is a top perspective view of a cover 506, without an insert installed therein, for a utility box, in accordance with various embodiments. In addition, FIG. 5B is a top view, FIG. 5C is a bottom view and FIG. 5D is a side cross-sectional view of the cover 506 shown in FIG. 5A. Referring to FIG. 5A, the cover 506 includes a through-hole 518 extending from a top surface 520 of the cover 506 to a bottom surface 522 of the cover 506. The through-hole 518 includes a shelf 524 in between the top surface 520 of the cover 506 and the bottom surface 322 of the cover 306, the portion of the through-hole 318 above the shelf 524 defining an upper recess 526 and the portion of the through-hole 518 below the shelf 524 defining a lower recess 528. As described and shown previously, a top plate of an insert is configured to be mounted in the upper recess 526 of the cover 506 while a bottom plate of the insert is configured to be mounted in the lower recess 528 of the cover 506.

In addition, FIG. 5A illustrates that the cover 506 defines cutaways 529a and 529b located on diametrically opposite sides of the cover 506. These cutaways 529a and 529b extend generally longitudinally along at least a portion of the outer surface 531 of an upper portion 532 of the cover 506. In addition, in the embodiment shown in FIG. 5A, the cutaways 529a and 529b are tapered such that, at the top surface 520, they define a relatively small semi-circular void 533, while at the lower edge of the upper portion 532, they define a relatively larger semi-circular void 534. These cutaways 529a and 529b may provide various different functions, e.g., locations at which the cover may be more easily grasped or levered for removal from the utility box, and/or locations at which gases or water within the utility box can escape so as to avoid over-pressurization, the backup or accumulation of fumes, etc. In the embodiment shown in FIG. 5A, the top surface 520 is molded so as to be blank, e.g., devoid of any logos, marking, indicia or the like.

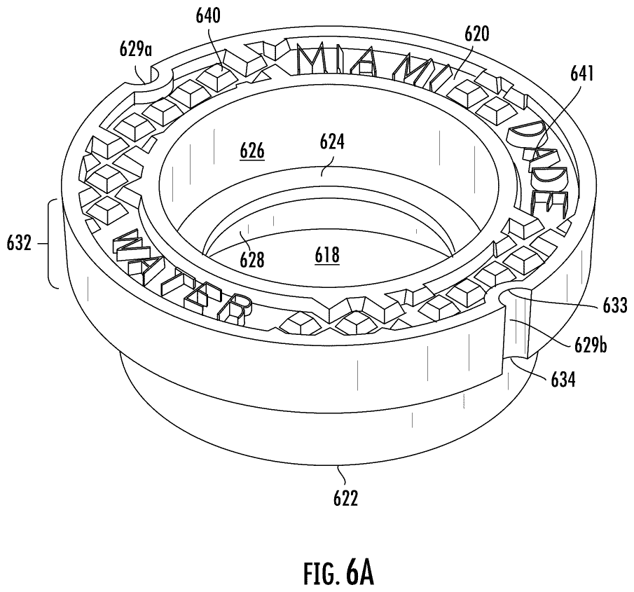

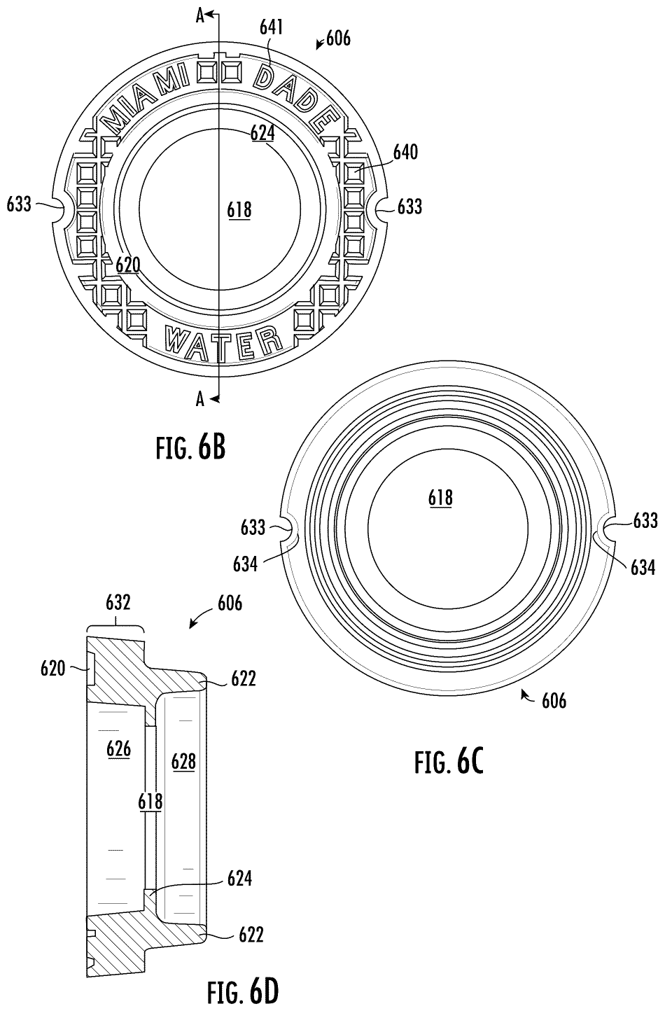

In another example, FIG. 6A is a top perspective view of a cover 606, without an insert installed therein, for a utility box, in accordance with various embodiments. In addition, FIG. 6B is a top view, FIG. 6C is a bottom view and FIG. 6D is a side cross-sectional view of the cover 606 shown in FIG. 6A. Referring to FIG. 6A, the cover 606 includes a through-hole 618 extending from a top surface 620 of the cover 606 to a bottom surface 622 of the cover 606. Unlike the blank top surface 520 shown in FIG. 5A, the top surface 620 may be customizable, e.g., molded in accordance with particular customer needs, such as to provide stiffening and/or traction features 640, or to have names or logos 641 that identify the manufacturer, utility entity or the like.

As in previously-describe embodiments, the through-hole 618 includes a shelf 624 in between the top surface 620 of the cover 606 and the bottom surface 622 of the cover 606, the portion of the through-hole 618 above the shelf 624 defining an upper recess 626 and the portion of the through-hole 618 below the shelf 624 defining a lower recess 628. As described and shown previously, a top plate of an insert is configured to be mounted in the upper recess 626 of the cover 606 while a bottom plate of the insert is configured to be mounted in the lower recess 628 of the cover 606.

Like the embodiment shown in FIG. 5A, FIG. 6A illustrates that the cover 606 defines cutaways 629a and 629b located on diametrically opposite sides of the cover 606 and that extend generally longitudinally along at least a portion of the outer surface 631 of an upper portion 632 of the cover 606. The cutaways 629a and 629b are also tapered such that, at the top surface 620, they define a relatively small semi-circular void 633, while at the lower edge of the upper portion 632, they define a relatively larger semi-circular void 634, enabling them to provide functions similar to those described above, e.g., grasping, pressure-relief, the backup or accumulation of fumes, etc.

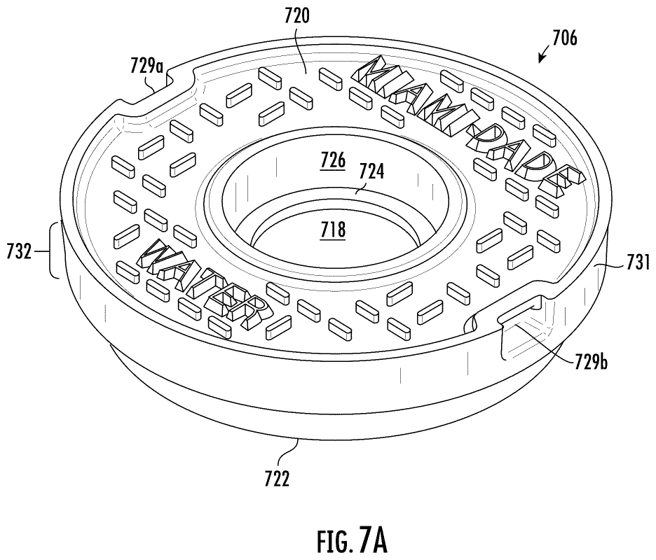

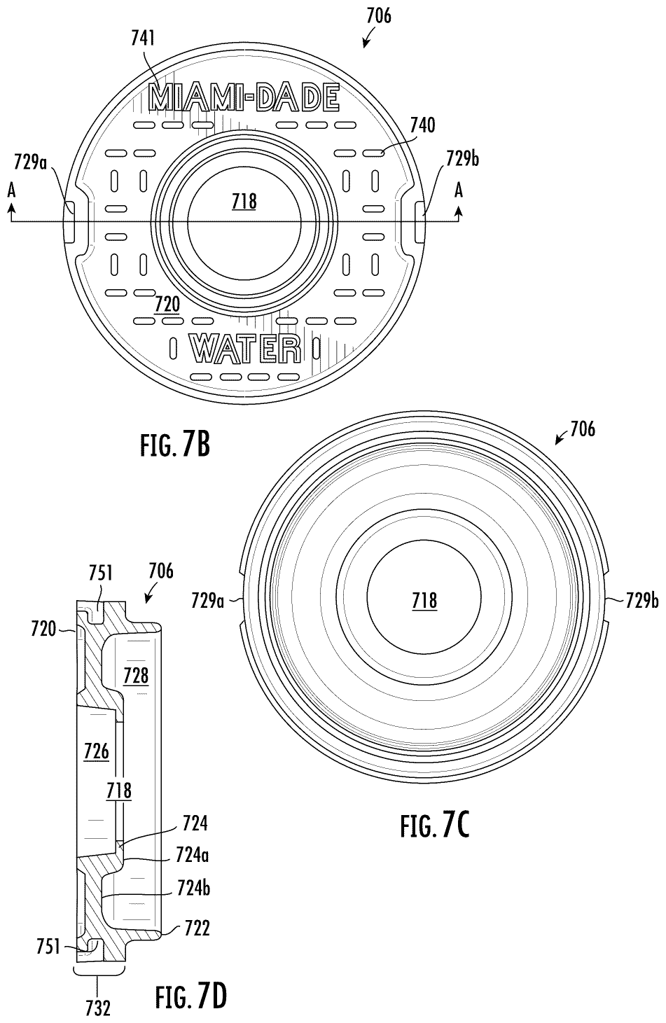

In still another example, FIG. 7A is a top perspective view of a cover 706, without an insert installed therein, for a utility box, in accordance with various embodiments. In addition, FIG. 7B is a top view, FIG. 7C is a bottom view and FIG. 7D is a side cross-sectional view of the cover 706 shown in FIG. 7A. Referring to FIG. 7A, the cover 706 again includes a through-hole 718 extending from a top surface 720 to a bottom surface 722 of the cover 706. Like the custom molded top surface 620 shown in FIG. 6A, the top surface 720 includes various features such as traction features 740 and utility entity identifiers 741. Of course, any type of information can be molded thereon, e.g., user instructions, safety warnings, utility types, etc.

As in previously-describe embodiments, the through-hole 718 includes a shelf 724 in between the top surface 720 and the bottom surface 722 of the cover 706, the portion of the through-hole 718 above the shelf 724 defining an upper recess 726 and the portion of the through-hole 718 below the shelf 724 defining a lower recess 728, enabling top and bottom plates of an lid insert to be mounted thereto.

Unlike the embodiments shown in FIGS. 5A and 6A, which illustrate cutaways 529a, 529b and 629a, 629b tapering longitudinally from the top surfaces 520, 620 to the lower edges of the upper portions 532, 632, the cover 706 defines cutaways 729a and 729b that are shaped generally rectangularly and that extend from the upper surface 720 only partly towards the lower edge of the upper portion 732. In addition, the cutaways 729a and 729b, located on diametrically opposite sides of the cover 706, each also include an undercut 751 so as to provide additional leverage for receiving a removal tool and/or functions similar to those described above, e.g., grasping, pressure-relief, the backup or accumulation of fumes, etc.

Still further, unlike the embodiments shown in FIGS. 5A and 6A, which illustrate the lower surfaces of the shelves 524, 624 having generally planar configurations, the embodiment shown in FIG. 7D illustrates a cover 706 having a shelf 724 with a lower surface 724a in the region of the through-hole 718. The cover also has a lower surface 724b, located on a different plane relative to lower surface 724a, radially further away from the through-hole 718. Such a non-planar shelf configuration may be advantageous for embodiments in which additional space is required below the cover, e.g., to accommodate instruments or antenna of different sizes and/or configurations within the utility box.

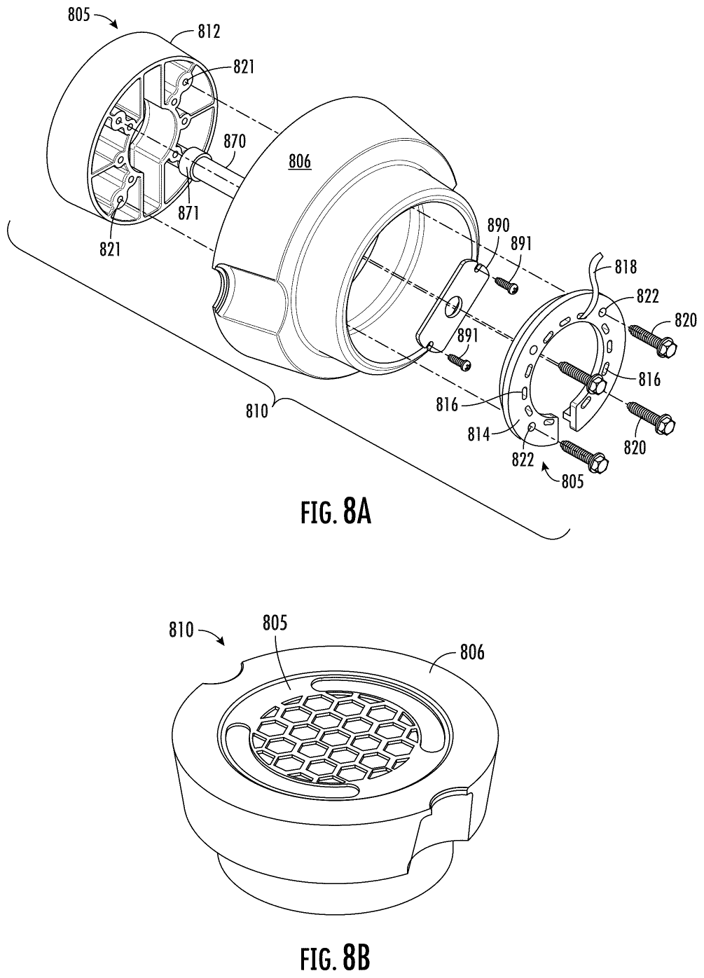

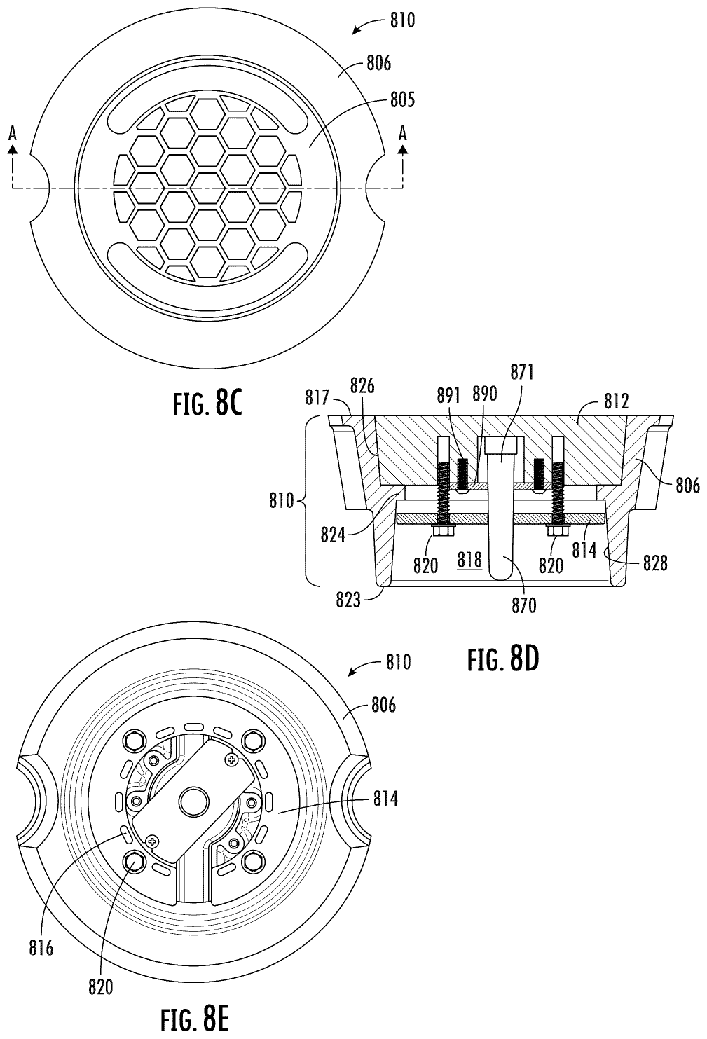

In accordance with another embodiment, FIGS. 8A-8E show an arrangement that is particularly well-suited for use with, e.g., geo-location instrumentation, although it may be employable with any other types of instrumentation. For example, FIG. 8A shows an exploded side perspective view of a lid 810 including an insert 805. The insert 805 includes a top plate 812 and a bottom plate 814, shown spaced apart in this exploded view. The lid 810 also includes a cover 806, the insert 805 configured to be assembled with a cover 806, as best shown and as described in FIG. 8D. Thus, the insert 805 and the cover 806 together form the lid 810 for a utility box (not shown), in accordance with various embodiments. According to this example embodiment, the lid 810 is configured for covering a utility box and mounting and/or supporting geo-location instrumentation, e.g., a geo-location instrument 870 having an antenna 871, housed therein. In this embodiment, the lid 810 also includes, for the purposes of mounting the geo-location instrumentation 870 and the antenna 871, a geo-location instrument retainer 890 which is attached to the upper plate 812 by one or more retainer hardware, e.g., bolts or screws, as will be further shown and described below, although it should be recognized that such instrumentation could be secured in this embodiment, or in any of the other described embodiments, by any such mechanical mounting mechanism, like brackets, plates, screws, or zip-ties, or may additionally or alternatively be secured by other means such as by adhesive, being potted in place with a castable material, etc. It should be noted that FIG. 8A is merely exemplary, and thus the shape and position of the various features illustrated therein, and in the other figures, are merely examples. Additional figures, illustrating specific embodiments of various features and functionality, will be provided in further detail below.

Still referring to the embodiment shown in FIG. 8A, the bottom plate 814 may define a plurality of fastener openings 816. Each fastener opening 816 is configured to optionally receive a fastener 818 for securing instrumentation. In embodiments in which the retainer 890 is not present, the fasteners 818 can be employed to mount, e.g., the geo-location instrumentation 870 and the antenna 871. In either case, the fasteners 818 and/or the retainer 890 may mount the instrumentation such that the antenna 871 can transmit a signal out of the utility box. In various embodiments, the fastener 818 may be a zip-tie or a screw or any other type of fastener 818.

As further shown in FIG. 8A, the top plate 812 and the bottom plate 814 are configured to be secured to each other by an insert attachment mechanism, such as by one or more screws or bolts (referred to as screws 820 hereinafter for simplicity only) that extend upwardly through holes 822 in the bottom plate 814 and into complementary openings 821 in the upper plate 812. It should be appreciated that the screws 820 may be self-tapping, e.g., may be configured to themselves create threads in the openings 821, or the openings 821 may instead have threaded inserts into which the screws 820 may be fastened.

FIG. 8B is a top perspective view of the lid 810, while FIG. 8C is a top view of the insert 810, and FIG. 8E is a bottom view of the lid 810. Referring now to FIG. 8D, there is shown a side cross-sectional view of the assembled insert 805 and the cover 806, taken along cross-section A-A of FIG. 8C. FIG. 8D shows the insert 805 assembled with a cover 806 so as to together form a lid 810 for use with a utility box, in accordance with various embodiments. As shown in FIG. 8D, the cover 806 may include a through-hole 818 extending from a top surface 817 of the cover 806 to a bottom surface 823 of the cover 806. The through-hole 818 may include a shelf 824 in between the top surface 817 of the cover 806 and the bottom surface 823 of the cover 806, the portion of the through-hole 818 above the shelf 824 defining an upper recess 826 and the portion of the through-hole 818 below the shelf 824 defining a lower recess 828. The top plate 812 of the insert 805 is configured to be mounted in the upper recess 826 of the cover 806 and a bottom plate 814 is configured to be mounted in the lower recess 828 of the cover 806. Advantageously, the top plate 812 and the bottom plate 814 are configured to be secured to each other, e.g, by the attachment screws 820, such that the shelf 824 is interposed between the top plate 812 and the bottom plate 814, thereby securing the insert 805 to the cover 806.

FIG. 8D also shows an instrument, e.g., such as the geo-location instrument 870, with an antenna 871 therein, in accordance with various embodiments. The instrument 870 is mounted to the underside of the upper plate 812 by a retainer, e.g., the retainer 890, and its associated mounting hardware, e.g., screws 891. Of course, it should be appreciated that the utility box (not shown here but an example of which is schematically shown in FIG. 2C) could have any number or any variety of different instruments and equipment disposed therein, the geo-location instrumentation 870 described herein being but a single example. Any type of utility box, utilized for housing any conceivable instrument having any conceivable purpose, is envisioned herein.

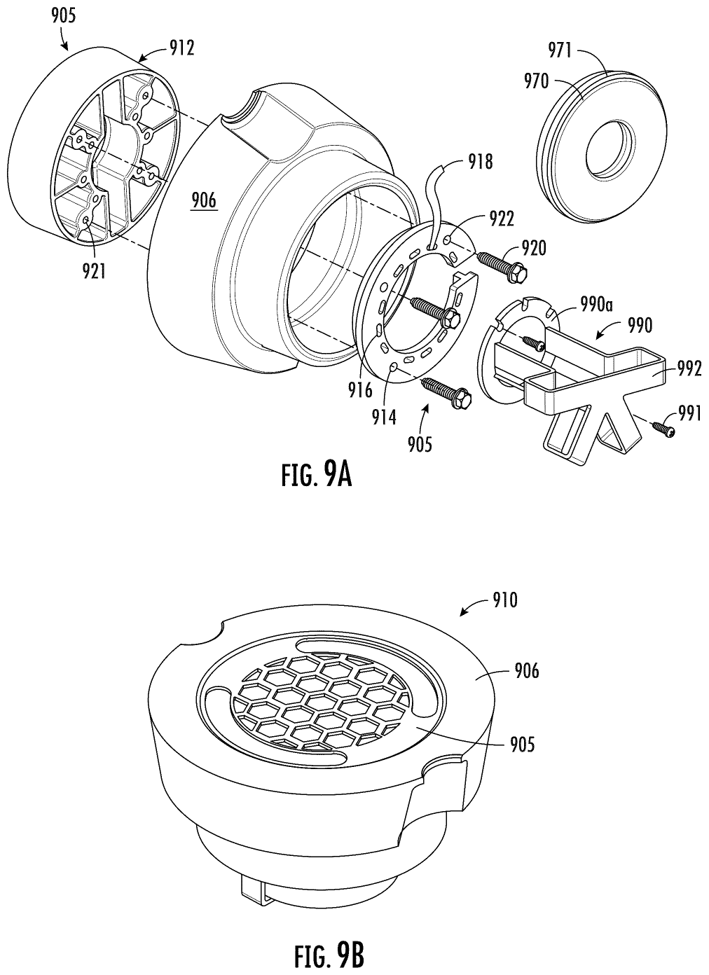

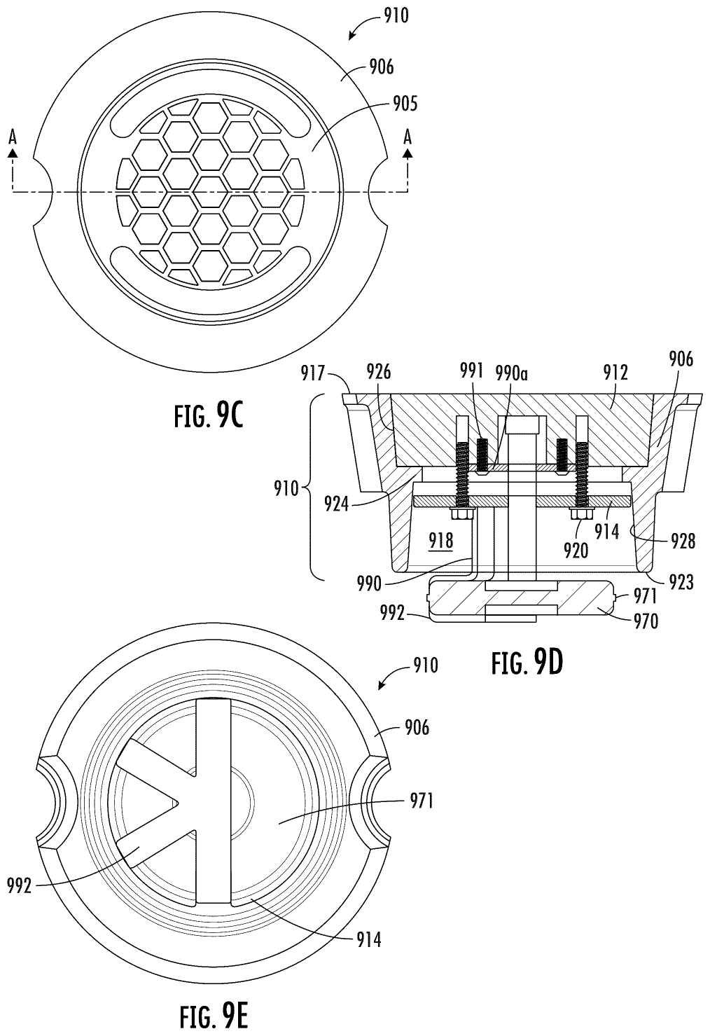

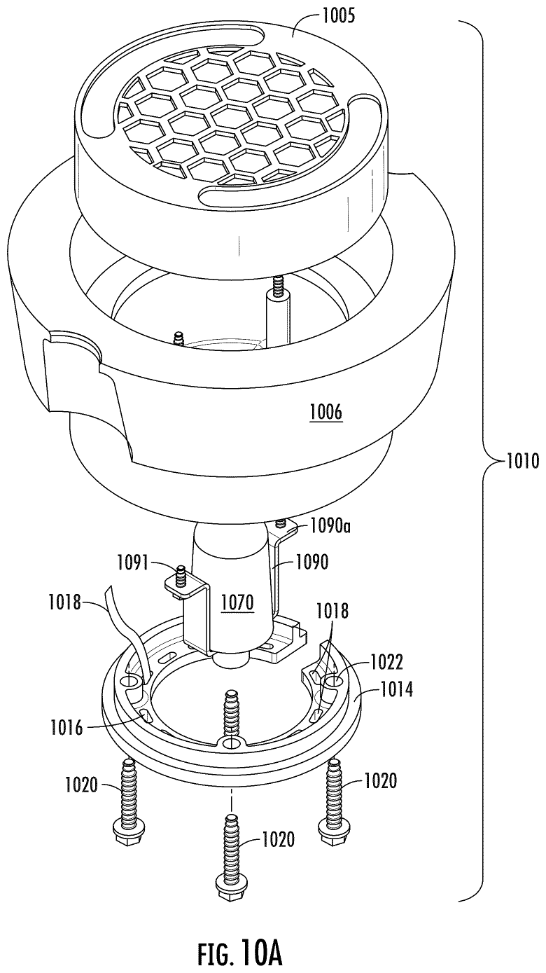

In accordance with another embodiment, FIGS. 9A-9E show an arrangement that is particularly well-suited for use with a different type of instrument, in this case a disk-shaped geo-location instrumentation that is mounted below the lid 910. For example, FIG. 9A shows an exploded side perspective view of a lid 910 including an insert 905. The insert 905 includes a top plate 912 and a bottom plate 914, shown spaced apart in this exploded view. The lid 910 also includes a cover 906, the insert 905 configured to be assembled with a cover 906, as best shown and as described in FIG. 9D. Thus, the insert 905 and the cover 906 together form the lid 910 for a utility box (not shown), in accordance with various embodiments. According to this example embodiment, the lid 910 is configured for covering a utility box and mounting and/or supporting geo-location instrumentation, e.g., a geo-location instrument disk 970 having an antenna 971, housed therein. In this embodiment, the lid 910 also includes, for the purposes of mounting the geo-location instrument disk 970 and the antenna 971, a geo-location instrument retainer 990. The geo-location instrument retainer 990 may include a mounting ring 990a which is attachable to the upper plate 912 by one or more retainer hardware, e.g., bolts or screws, as will be further shown and described below. The geo-location instrument retainer 990 may also include a portion that extends downwardly to a retainer housing 992a that is configured to selectively receive the geo-location instrument disk 970. It should be noted that FIG. 9A is merely exemplary, and thus the shape and position of the various features illustrated therein, and in the other figures, are merely examples. Additional figures, illustrating specific embodiments of various features and functionality, will be provided in further detail below.

Still referring to the embodiment shown in FIG. 9A, the bottom plate 914 may define a plurality of fastener openings 916. Each fastener opening 916 is configured to optionally receive a fastener 918 for securing instrumentation. The fasteners 918 and/or the retainer 990 may mount instrumentation such that the antenna 971 can transmit a signal out of the utility box. In various embodiments, the fastener 918 may be a zip-tie or a screw or any other type of fastener 918.

As further shown in FIG. 9A, the top plate 912 and the bottom plate 914 are configured to be secured to each other by an insert attachment mechanism, such as by one or more screws or bolts (referred to as screws 920 hereinafter for simplicity only) that extend upwardly through holes 922 in the bottom plate 914 and into complementary openings 921 in the upper plate 912. As above, it should be appreciated that the screws 920 may be self-tapping, e.g., may be configured to themselves create threads in the openings 921, or the openings 921 may instead have threaded inserts into which the screws 920 may be fastened.

FIG. 9B is a top perspective view of the lid 910, while FIG. 9C is a top view of the lid 910, and FIG. 9E is a bottom view of the lid 910. Referring now to FIG. 9D, there is shown a side cross-sectional view of the assembled insert 905 and the cover 906, taken along cross-section A-A of FIG. 9C. FIG. 9D shows the insert 905 assembled with the cover 906 so as to together form the lid 910 for use with a utility box, in accordance with various embodiments. As shown in FIG. 9D, the cover 906 may include a through-hole 918 extending from a top surface 917 of the cover 906 to a bottom surface 923 of the cover 906. The through-hole 918 may include a shelf 924 in between the top surface 917 of the cover 906 and the bottom surface 923 of the cover 906, the portion of the through-hole 918 above the shelf 924 defining an upper recess 926 and the portion of the through-hole 918 below the shelf 924 defining a lower recess 928. The top plate 912 of the insert 905 is configured to be mounted in the upper recess 926 of the cover 906 and a bottom plate 914 is configured to be mounted in the lower recess 928 of the cover 906. Advantageously, the top plate 912 and the bottom plate 914 are configured to be secured to each other, e.g., by the attachment screws 920, such that the shelf 924 is interposed between the top plate 912 and the bottom plate 914, thereby securing the insert 905 to the cover 906.

FIG. 9D also shows an instrument, e.g., such as the geo-location instrument disk 970, with an antenna 971 therein, in accordance with various embodiments. The instrument disk 970 is mounted to the underside of the upper plate 912 by the mounting ring 990a of the retainer 990 being attached thereto by, e.g., screws 991. The retainer 990 extends downwardly to the retainer housing 992 in which the geo-location instrument disk 970 is housed. Of course, it should be appreciated that the utility box (not shown) could have any number or any variety of different instruments and equipment disposed therein, the geo-location instrumentation disk 970 described herein being but a single example. As mentioned above, any type of utility box, utilized for housing any conceivable instrument having any conceivable purpose, is envisioned herein.

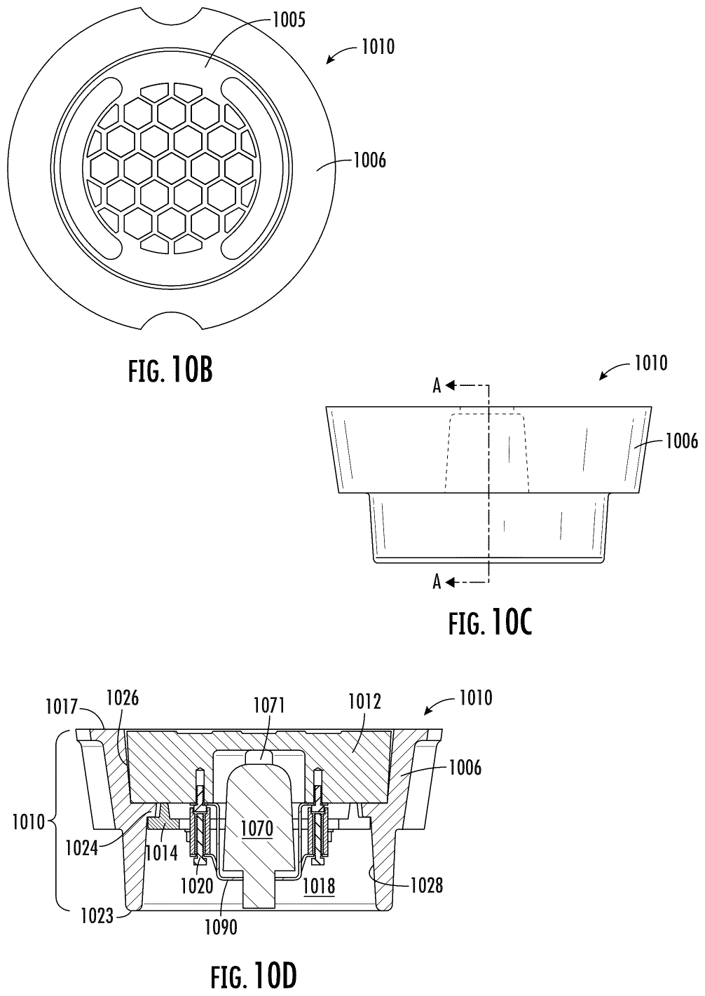

In accordance with still another embodiment, FIGS. 10A-10D show an arrangement that is particularly well-suited for use with a still different type of instrument, in this case cellular communication instrumentation that is mounted below the lid 1010. In the embodiment shown, the cellular communication instrumentation is a Laird™ Phantom cellular antenna, sold by Laird External Antennas of TE Connectivity, of Berwyn, Pennsylvania, USA, although any cellular communication instrument or system is envisioned. For example, FIG. 10A shows an exploded side perspective view of a lid 1010 including an insert 1005. The insert 1005 includes a top plate 1012 and a bottom plate 1014, shown spaced apart in this exploded view. The lid 1010 also includes a cover 1006, the insert 1005 configured to be assembled with a cover 1006, as best shown and as described in FIG. 10D. Thus, the insert 1005 and the cover 1006 together form the lid 1010 for a utility box (not shown), in accordance with various embodiments. According to this example embodiment, the lid 1010 is configured for covering a utility box and mounting and/or supporting cellular communication instrumentation, e.g., a cellular communication antenna housing having an antenna 1071 housed therein. In this embodiment, the lid 1010 also includes, for the purposes of mounting the cellular communication instrument 1070 and the antenna 1071, a cellular communication instrument retainer 990. The cellular communication instrument retainer 1090 may include a U-shaped mounting bracket 1090 having tabs 1090a which are attachable to the upper plate 1012 by one or more retainer hardware, e.g., bolts or screws, as will be further shown and described below. It should be noted that FIG. 10A is merely exemplary, and thus the shape and position of the various features illustrated therein, and in the other figures, are merely examples. Additional figures, illustrating specific embodiments of various features and functionality, will be provided in further detail below.

Still referring to the embodiment shown in FIG. 10A, the bottom plate 1014 may define a plurality of fastener openings 1016. Each fastener opening 1016 is configured to optionally receive a fastener 1018 for securing instrumentation. The fasteners 1018 and/or the cellular communication retainer 1090 may mount instrumentation such that the cellular communication antenna 1071 can transmit a signal out of the utility box. In various embodiments, the fastener 1018 may be a zip-tie or a screw or any other type of fastener 1018.

As further shown in FIG. 10A, the top plate 1012 and the bottom plate 1014 are configured to be secured to each other by an insert attachment mechanism, such as by one or more screws or bolts (referred to as screws 1020 hereinafter for simplicity only) that extend upwardly through holes 1022 in the bottom plate 1014 and into complementary openings 1021 in the upper plate 1012. As above, it should be appreciated that the screws 1020 may be self-tapping or the openings 1021 may instead have threaded inserts into which the screws 1020 may be fastened.

FIG. 10B is a top view of the lid 1010, while FIG. 10C is a side view of the lid 910. Referring now to FIG. 10D, there is shown a side cross-sectional view of the assembled insert 1005 and the cover 1006, taken along cross-section A-A of FIG. 10C. FIG. 10D shows the insert 1005 assembled with the cover 1006 so as to together form the lid 1010 for use with the cellular communication equipment box, in accordance with various embodiments. As shown in FIG. 10D, the cover 1006 may include a through-hole 1018 extending from a top surface 1017 of the cover 1006 to a bottom surface 1023 of the cover 1006. The through-hole 1018 may include a shelf 1024 in between the top surface 1017 of the cover 1006 and the bottom surface 1023 of the cover 1006, the portion of the through-hole 1018 above the shelf 1024 defining an upper recess 1026 and the portion of the through-hole 1018 below the shelf 1024 defining a lower recess 1028. The top plate 1012 of the insert 1005 is configured to be mounted in the upper recess 1026 of the cover 1006 and a bottom plate 1014 is configured to be mounted in the lower recess 1028 of the cover 1006. Advantageously, the top plate 1012 and the bottom plate 1014 are configured to be secured to each other, e.g, by the attachment screws 1020, such that the shelf 1024 is interposed between the top plate 1012 and the bottom plate 1014, thereby securing the insert 1005 to the cover 1006.

FIG. 10D also shows an instrument, e.g., such as the cellular communication instrument 1070, with an antenna 1071 therein, in accordance with various embodiments. The cellular communication instrument 1070 is mounted to the underside of the upper plate 1012 by the tabs 1090a being attached thereto by screws 1091. The U-shaped retainer 1090 extends downwardly such that the cellular communication instrument 1070 rests upon the lower portion of the bracket. Of course, it should be appreciated that the utility box (not shown) could have any number or any variety of different instruments and equipment disposed therein, the cellular communication instrumentation 1070 described herein being but a single example. As mentioned above, any type of utility box, utilized for housing any conceivable instrument having any conceivable purpose, is envisioned herein.

As set forth above, while some of the above-described embodiments illustrate both an upper plate and a bottom plate being connected to each other, it should be recognized that, in other embodiments, there is only a single plate having screws or bolts that pass directly into an upper plate without the need for a bottom plate. For example, FIGS. 11A-11C illustrate an alternative arrangement in which only a single plate is employed. FIG. 11A shows an exploded side perspective view of a lid 1110 including an insert 1105. The insert 1105 includes a top plate 1112. The lid 1110 also includes a cover 1106, the insert 1105 configured to be assembled with the cover 1106, as best shown and as described in FIG. 11B and C. Thus, the insert 1105 and the cover 1106 together form the lid 1110 for a utility box (not shown), in accordance with various embodiments. According to this example embodiment, the lid 1110 is configured for covering such a utility box and mounting and/or supporting various types of instrumentation therein.

The lid 1110 may also include, for the purposes of mounting instrumentation and/or an antenna, an instrument retainer (not shown) which is attached to the upper plate 1112 by one or more retainer hardware, e.g., bolts or screws, although it should be recognized that such instrumentation could be secured in this embodiment, or in any of the other described embodiments, by any such mechanical mounting mechanism, like brackets, plates, screws, or zip-ties, or may additionally or alternatively be secured by other means such as by adhesive, being potted in place with a castable material, etc. It should be noted that FIG. 11A is merely exemplary, and thus the shape and position of the various features illustrated therein, and in the other figures, are merely examples.

Still referring to the embodiment shown in FIG. 11A, instead of a bottom plate as provided in other embodiments, the cover 1106 defines a through-hole 1118 from which extends in the radially-inward direction a shelf 1124. At various circumferentially-spaced locations along the shelf 1124, the shelf 1124 includes tabs 1114 each having a hole 1114a disposed therethrough. Above the shelf 1124 is an upper recess 1126 into which the insert 1105 is configured to be seated. When the upper plate 1112 of the insert 1105 is mounted in the upper recess 1126 of the cover 1106, the upper plate 1112 is configured to be secured to the tabs 1114, e.g, by attachment screws 1120 extending through the holes 1114a and into the openings 1121 of the insert 1105, for example by screws 1120 that extend upwardly through holes 1114a in the tabs 1114 and into complementary openings 1121 in the upper plate 1112. It should be appreciated that the screws 1120 may be self-tapping, e.g., may be configured to themselves create threads in the openings 1121, or the openings 1121 may instead have threaded inserts into which the screws 1120 may be fastened.

FIG. 11B is a top view of the insert 1110. FIG. 11C is a side cross-sectional view of the assembled insert 1105 and the cover 1106, taken along cross-section A-A of FIG. 11B. FIG. 11C shows the insert 1105 assembled with a cover 1106 so as to together form a lid 1110 for use with a utility box, in accordance with various embodiments. As shown in FIG. 11C, the cover 1106 may include a through-hole 1118 extending from a top surface 1117 of the cover 1106 to a bottom surface 1123 of the cover 1106. Within this through-hole 1118 may be an instrument (not shown), e.g., such as the geo-location instrument 870 with an antenna 871 shown in FIG. 8.

As set forth above, while various of the above-described embodiments illustrate certain mechanisms to connect the upper plate and the bottom plate to each other, there is no limitation on the various different ways that such connections may be achieved and that the same type of connection could be achieved, in other contemplated embodiments, via snap-in or push-on features. FIGS. 12A through 15D illustrate an example embodiment in which upper and bottom plates may be connected, e.g., via a snap-fit type connection system.

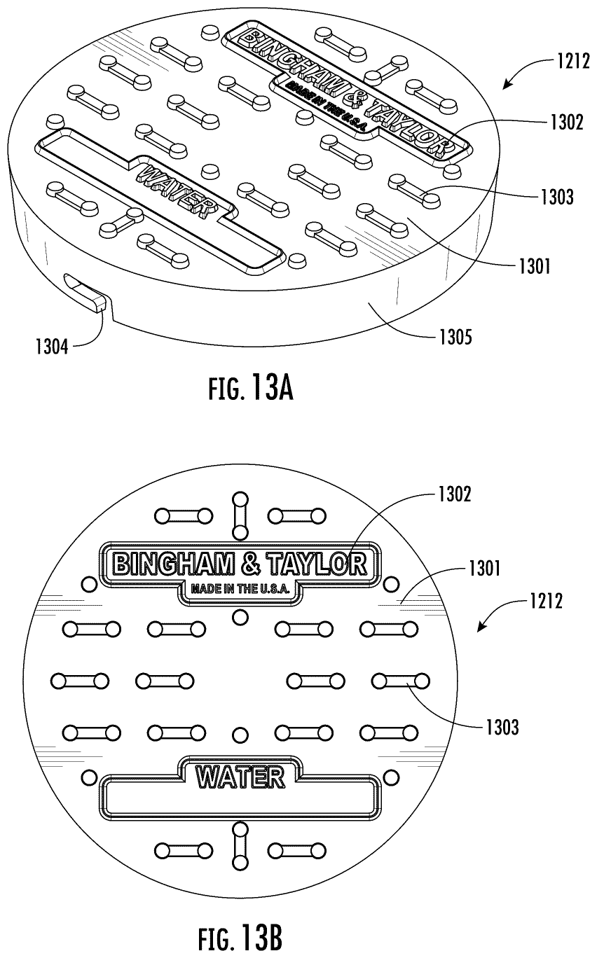

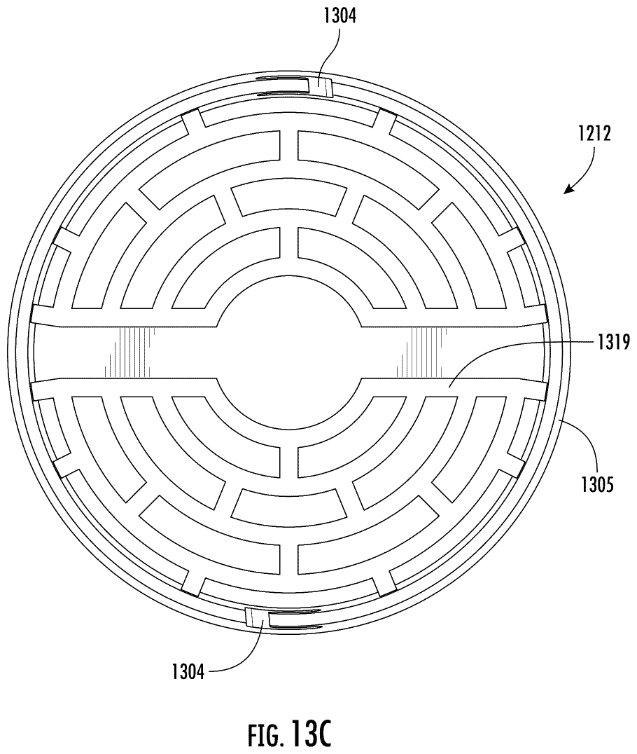

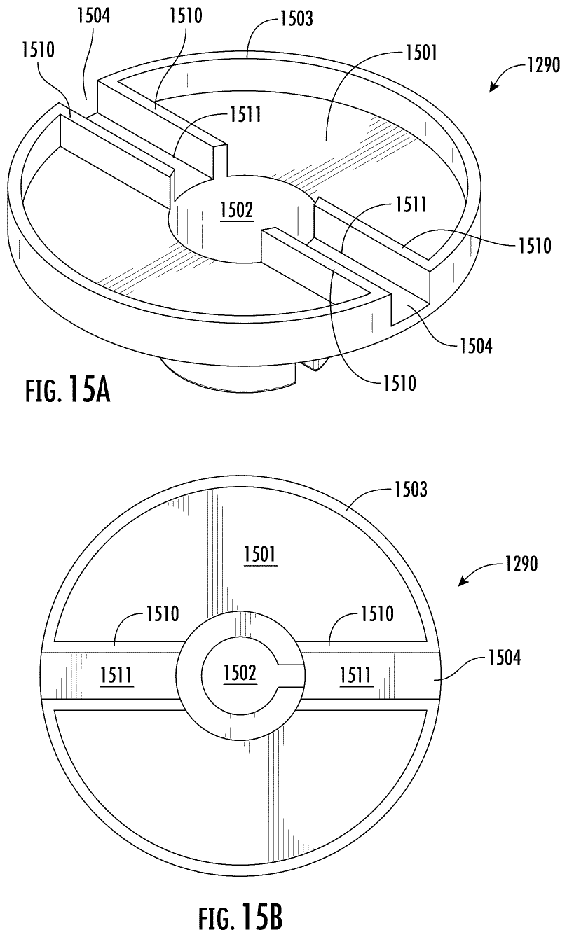

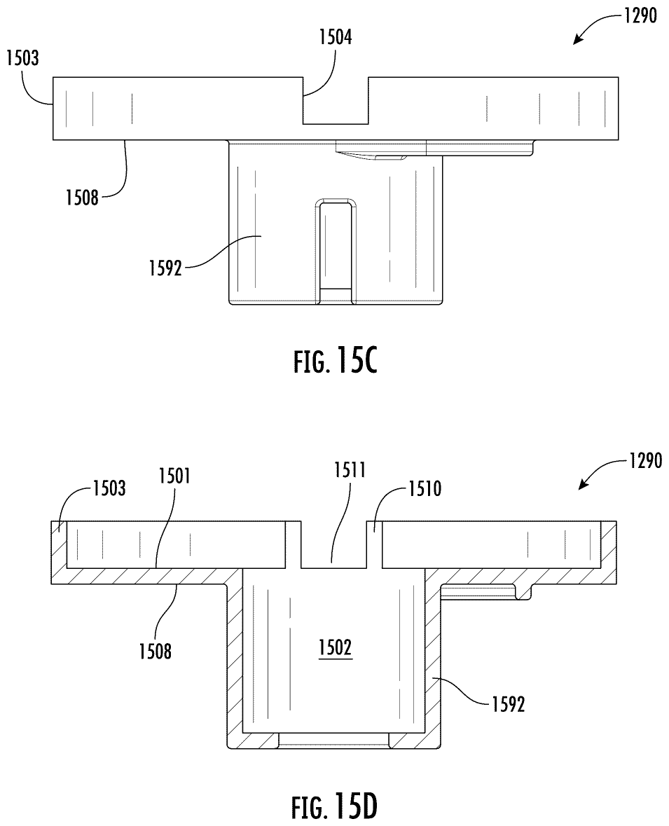

For example, FIG. 12A shows a cutaway top perspective view of a lid 1210 including an insert 1205. The insert 1205 includes a top plate 1212 and a bottom plate 1214. The lid 1210 also includes a cover 1206, the insert 1205 configured to be assembled with the cover 1206. The insert 1205 and the cover 1206 together form the lid 1210. According to this example embodiment, the lid 1210 is configured for covering a utility box (not shown but may be similar to the utility box shown schematically in FIG. 2C) and mounting and/or supporting various instrumentation having an antenna (also not shown in this view). In this embodiment, the lid 1210 also includes, for the purposes of mounting such and antenna, an instrument/antenna retainer 1290, described in further detail in FIGS. 15A-15D. Prior to describing how these components are assembled together, attention is now directed to FIGS. 13-15, which illustrate some specific features of these components.

For example, FIGS. 13A-13C illustrate certain features of the top plate 1212, according to various embodiments. FIG. 13A shows the top plate 1212 in a top perspective view including a top surface 1301 onto which customizable logos or words 1302 may be molded. The top surface 1301 may also include surfaces features 1303, which may include treads, vent holes, markings, or any other conceivable features. As shown in FIG. 13A, the top plate 1212 may also include slots 1304 at one or more locations along its circumferential edge 1305. FIG. 13B illustrates the top plate 1212 in a top view while FIG. 13C illustrates the top plate 1212 in a bottom view. Shown in FIG. 13C are, on a bottom surface of the top plate 121, a plurality of ribs 1319 that may provide structural integrity and load strength to the top plate 1212.

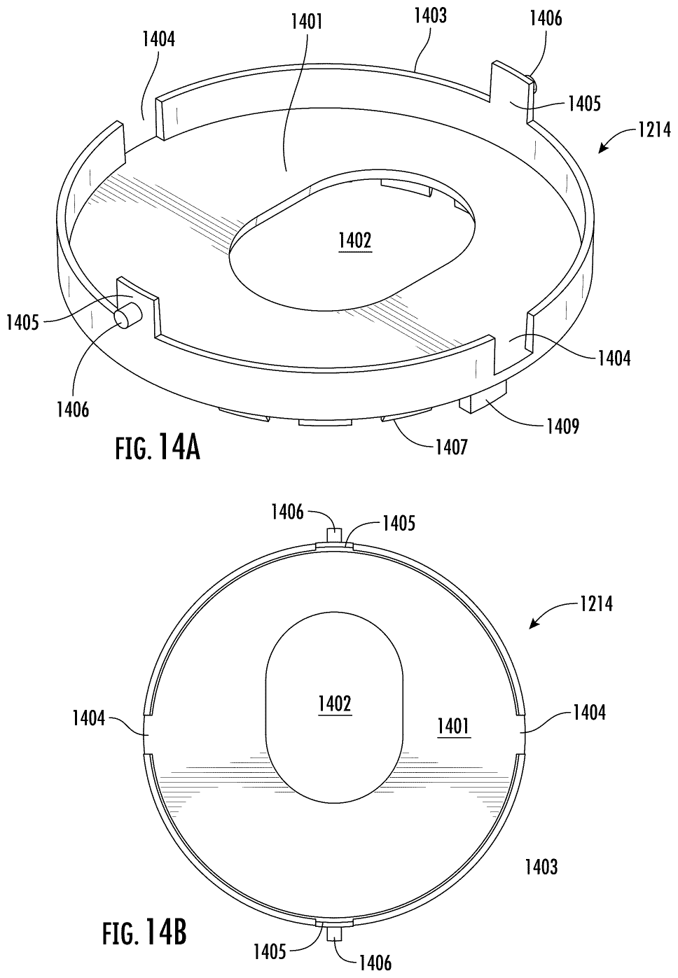

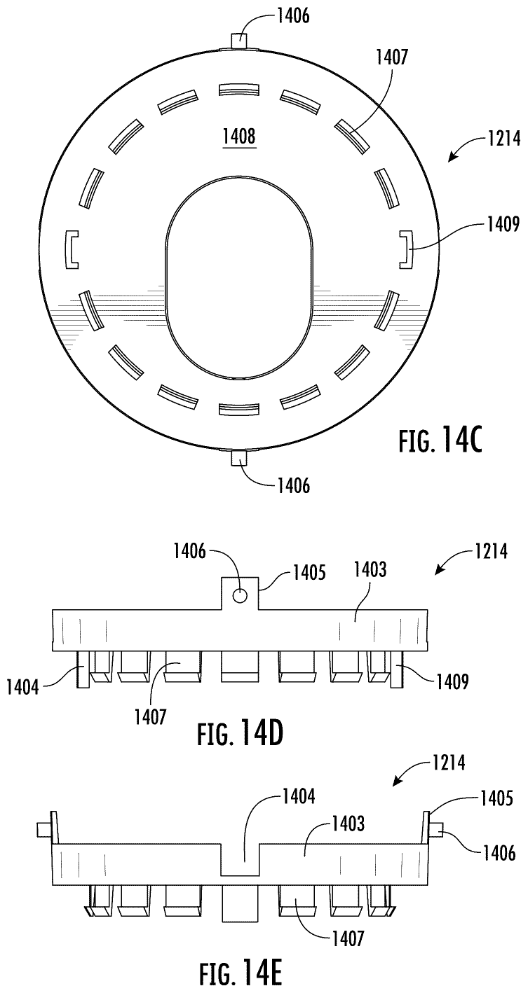

FIGS. 14A-14C, on the other hand, illustrate certain features of the bottom plate 1214, according to various embodiments. FIG. 14A shows the bottom plate 1214 in a top perspective view including a top surface 1401 defining a through-hole 1402. Extending upwardly from the top surface 1401 is a circumferential rim 1403 having openings 1404 defined. Extending upwardly from the circumferential rim 1403 are tabs 1405, and extending radially outwardly from the tabs 1405 are pins 1406. FIG. 14B illustrates the bottom plate 1214 in a top view.

FIG. 14C illustrates the bottom plate 1214 in a bottom view. FIG. 14C illustrates, extending downwardly from a bottom surface 1408 of the bottom plate 1214, a plurality of circumferentially-disposed tabs 1407 (in this case, the tabs are located slightly inward of the outermost circumference of the bottom plate 1214). Also extending downwardly from the bottom surface 1408 of the bottom plate 1214 are a plurality of, in this case two, oppositely-disposed fingers 1409. FIGS. 14D and 14E are side views of the bottom plate 1214 illustrating the circumferentially-disposed tabs 1407 and the oppositely-disposed fingers 1409 extending downwardly from the bottom surface 1408 of the bottom plate 1214.

Still further, FIGS. 15A-15C illustrate certain features of instrument/antenna retainer 1290, according to various embodiments. FIG. 15A shows the instrument/antenna retainer 1290 in a top perspective view including a top surface 1501 defining a through-hole 1502. Extending upwardly from the top surface 1501 is a circumferential rim 1503 having openings 1504 that extend radially inwardly via walls 1510 to define channels 1511. FIG. 15B illustrates the instrument/antenna retainer 1290 in a top view.

FIG. 15C illustrates the instrument/antenna retainer 1290 in a side view, while FIG. 15D illustrates the instrument/antenna retainer 1290 in a side cross-sectional view. FIGS. 15C and 15D illustrate, extending downwardly from a bottom surface 1508 of the instrument/antenna retainer 1290, a retainer housing 1592 that is configured to selectively receive an instrument and/or antenna. It should be noted that FIG. 15A-15D are merely exemplary, and thus the shape and position of the various features illustrated therein, and in the other figures, are merely examples.

Referring back now to FIG. 12B, there is shown a top view of the assembled lid 1210, while FIG. 12C is a bottom view thereof. FIG. 12D, on the other hand, illustrates a side cross-sectional view of the assembled insert 1205 and the cover 1206, taken along cross-section D-D of FIG. 12B. FIG. 12D shows the insert 1205 assembled with the cover 1206 so as to together form the lid 1210 for use with a utility box, in accordance with various embodiments. As shown in FIG. 12D, the pins 1406 of the bottom plate 1214 are received and rotated within the slots 1304 of the top plate 1212 so as to twist-lock the top plate 1212 and the bottom plate 1214 together. The circumferentially-disposed tabs 1407 of the bottom plate 1214 are snap-fit onto a bottom inner circumferential lip 1219 of the cover 1206 so as to securely maintain the entire lid 1210 to the cover 1206. The instrument/antenna retainer 1290 is disposed between the top plate 1212 and the bottom plate 1214 with the retainer housing 1592 extending downwardly through the opening 1402 of the bottom plate 1214. As set forth above, the retainer housing 1592 is configured to receive and securely maintain a wide variety of different types and shapes of instruments and antennas, thereby ensuring that the lid 1210 is suitable for receiving virtually any brand of antenna and effectively transmitting signals therethrough.

In accordance with one or more of the above-described embodiments, there may also be provided a method of assembling a lid for a utility box. For the purposes of example only, the method is described hereinbelow in connection with a leak detection instrument, although it should be appreciated that the method may also be employed for systems that employ any other type of instruments and/or monitoring equipment. The method may include the step of providing a cast-iron cover configured to be mounted on the utility box, the cover including an upper recess and a lower recess with a shelf disposed therebetween. The method may include the step of providing a plastic insert top plate and providing a plastic insert bottom plate having a fastening mechanism configured to secure an antenna. The method may also include the step of mounting the insert top plate and the insert bottom plate to the cover by securing the top plate to the bottom plate, with the top plate residing in the upper recess and the bottom plate residing in the lower recess and having the shelf interposed therebetween. As set forth above, the fastening mechanism may be at least one opening for receiving at least one of a zip-tie and/or a screw. The mounting step may include screwing the insert top plate to the insert bottom plate, and/or the mounting step may include twist-locking the insert top plate to the insert bottom plate.

Still further, the method may include the step of mounting the lid on a utility box having a leak detection instrument therein, the leak detection instrument including the antenna (recognizing that leak detection is merely one example of the type of instrumentation that may be employed with this method). In addition, the method may include the step of fastening the antenna to the insert bottom plate via the fastening mechanism such that the antenna is positioned to transmit a leak detection signal through the lid.

As mentioned previously, a particular advantage of the lid insert and cover described hereinabove is that they include structural features that render them suitable for effectively securing various different types of antennae (even when existing antennae are replaced by new antennae having different sizes and configurations), while still ensuring that the lid allows signals to be transmitted therethrough. Thus, the method described above can also include the steps of, in the field, unfastening the antenna from the fastening mechanism, replacing the antenna of the leak detection instrument with a different antenna, and fastening the different antenna to the bottom plate via the fastening mechanism such that the different antenna is also positioned to transmit a leak detection signal through the lid.

There are no limitations in terms of the particular embodiments described in this application, which are intended as illustrations of various aspects only. Many modifications and variations can be made without departing from its spirit and scope, as will be apparent to those skilled in the art. Functionally equivalent methods and apparatuses, in addition to those enumerated herein, will be apparent to those skilled in the art from the foregoing descriptions. Such modifications and variations are intended to fall within the scope of the appended claims. Only the terms of the appended claims are intended to be limiting, along with the full scope of equivalents to which such claims are entitled. It is also to be understood that the terminology used herein, e.g., “and”, “or”, “including”, “at least” as well as the use of plural or singular forms, etc., is for the purpose of describing examples of embodiments and is not intended to be limiting.

What is claimed is:

1. A lid for mounting on a utility box, the utility box housing an antenna therein, the lid comprising:
a cover configured to be mounted on the utility box;
an insert configured to be mounted to the cover, the insert including a plurality of fastening mechanisms configured to secure the antenna such that the antenna can transmit a signal out of the utility box.

2. The lid of claim 1, wherein the antenna is selected from a plurality of different antenna configurations, and fastening mechanism is configured to secure any one of the plurality of different antenna configurations antenna such that any one of the plurality of different antenna configurations can transmit a signal out of the utility box.

3. The lid of claim 1, wherein the at least one fastening mechanism is an opening for receiving at least one of a zip-tie, a bracket and a screw.

4. The lid of claim 1, wherein the cover includes a through-hole extending from a top surface of the cover to a bottom surface of the cover, the through-hole including a shelf in between the top surface of the cover and the bottom surface of the cover, the portion of the through-hole above the shelf defining an upper recess and the portion of the through-hole below the shelf defining a lower recess.

5. The lid of claim 4, wherein the insert comprises:
a top plate configured to be mounted in the upper recess of the cover; and
a bottom plate configured to be mounted in the lower recess of the cover.

6. The lid of claim 1, wherein the insert includes a top plate configured to be mounted in an upper recess of the cover by fastening mechanisms that extend through the cover.

7. The lid of claim 5, wherein the top plate and the bottom plate are configured to be secured to each other, with the shelf interposed therebetween, by at least one of a screw, a bolt, a snap-in feature, a push-on feature, an adhesive or tape extending between the bottom plate and the upper plate, a hook and loop (Velcro), or by welding, including thermal/friction ans ultrasonic.

8. The lid of claim 5, wherein the top plate and the bottom plate are configured to be secured to each other, with the shelf interposed therebetween, by a twist lock mechanism that secures the bottom plate to the upper plate.

9. The lid of claim 8, wherein the twist lock mechanism includes a plurality of complementary slots and tabs that secure the bottom plate to the upper plate.

10. The lid of claim 9, wherein the twist lock mechanism includes one or more of a spring, wave washer, a rubber gasket or an o-ring to apply a force that helps maintain the complementary tabs within the slots so as to secure the bottom plate to the upper plate.

11. The lid of claim 1, wherein the utility box houses an instrument, and the antenna is configured to transmit a signal generated by the instrument.

12. The lid of claim 11, wherein the instrument includes at least one of a leak detection instrument, a geo-location instrument or an electrical current or electrical load sensing instrument, and the antenna is configured to transmit one or more respective signal generated by the leak detection instrument, the geo-location instrument or the electrical current or electrical load sensing instrument.

13. An insert for mounting to a utility box cover of a utility box, the utility box housing an antenna therein, the insert comprising:
a top plate configured to be mounted in an upper recess of the cover;
a bottom plate configured to be mounted in a lower recess of the cover; and
the bottom plate defining a plurality of fastener openings, each fastener opening configured to receive a fastener for securing the antenna such that the antenna can transmit a signal out of the utility box.

14. The insert of claim 13, wherein the fastener is one of a zip-tie, a bracket, and a screw.

15. The insert of claim 13, wherein the top plate and the bottom plate are configured to be secured to each other, with at least a portion of the utility box cover plate interposed therebetween, by an insert attachment mechanism.

16. The insert of claim 15, wherein the insert attachment mechanism includes at least one of a screw, a bolt, a snap-in feature, a push-on feature, and an adhesive extending between the bottom plate and the upper plate.

17. The insert of claim 15, wherein the insert attachment mechanism includes a twist lock mechanism that secures the bottom plate to the upper plate.

18. The insert of claim 17, wherein the twist lock mechanism includes a plurality of complementary slots and tabs that secure the bottom plate to the upper plate.

19. The insert of claim 17, wherein the twist lock mechanism includes one of a wave washer, a rubber gasket or an o-ring to apply a force that helps maintain the tabs within the complementary slots so as to secure the bottom plate to the upper plate.

20. The insert of claim 17, wherein the twist lock mechanism includes at least one anti-backout feature so as to help secure the tabs within the complementary slots.

21. The insert of claim 13, wherein the utility box houses of least one of a leak detection instrument and a geo-location instrument, and the antenna is configured to transmit a signal generated by the leak detection or geo-location instrument.

22. The insert of claim 13, wherein the insert is manufactured from plastic.

23. A method for assembling a lid for a utility box, the method comprising the steps of:
providing a cast-iron cover configured to be mounted on the utility box, the cover including an upper recess and a lower recess with a shelf disposed therebetween;
providing a plastic insert top plate;
providing a plastic insert bottom plate having a fastening mechanism configured to secure an antenna; and
mounting the insert top plate and the insert bottom plate to the cover by securing the top plate to the bottom plate, with the top plate residing in the upper recess and the bottom plate residing in the lower recess and having the shelf interposed therebetween.

24. The method of claim 23, wherein the fastening mechanism is at least one opening for receiving at least one of a zip-tie and a screw.

25. The method of claim 23, wherein the mounting step includes screwing the insert top plate to the insert bottom plate.

26. The method of claim 23, wherein the mounting step includes twist-locking the insert top plate to the insert bottom plate.

27. The method of claim 23, further comprising the steps of:
mounting the lid on a utility box having a leak detection instrument therein, the leak detection instrument including the antenna;
fastening the antenna to the insert bottom plate via the fastening mechanism such that the antenna is positioned to transmit a leak detection signal through the lid.

28. The method of claim 27, further comprising the steps of:
unfastening the antenna from the fastening mechanism;
replacing the antenna of the leak detection instrument with a different antenna;
fastening the different antenna to the bottom plate via the fastening mechanism such that the different antenna is also positioned to transmit a leak detection signal through the lid.

29. The method of claim 23, further comprising the steps of:
mounting the lid on a utility box having a geo-location instrument therein, the geo-location instrument including the antenna;
fastening the antenna to the insert bottom plate via the fastening mechanism such that the antenna is positioned to transmit a geo-location signal through the lid.

30. The method of claim 29, further comprising the steps of:
unfastening the antenna from the fastening mechanism;
replacing the antenna of the geo-location instrument with a different antenna;
fastening the different antenna to the bottom plate via the fastening mechanism such that the different antenna is also positioned to transmit a geo-location signal through the lid.

31. The method of claim 23, further comprising the steps of: molding the top insert plate with a tool having a customizable text or logo.
